(19) United States
(12) Patent Application Publication
(10) Pub. No.: US 2021/0091247 A1
(43) Pub. Date: Mar. 25, 2021

(54) Interconnection of solar cell modules

(71) Applicant: SolAero Technologies Corp., Albuquerque, NM (US)

(72) Inventors: Daniel Aiken, Cedar Crest, NM (US); Lei Yang, Albuquerque, NM (US); Daniel Derkacs, Albuquerque, NM (US); Greg Flynn, Albuquerque, NM (US); Benjamin Richards, Albuquerque, NM (US); Marvin B Clevenger, Albuquerque, NM (US)

(73) Assignee: SolAero Technologies Corp., Albuquerque, NM (US)

(21) Appl. No.: 17/010,134

(22) Filed: Sep. 2, 2020

Related U.S. Application Data
(62) Division of application No. 15/841,779, filed on Dec. 14, 2017.
Application No. 15/841,779 is a continuation-in-part of application No. 14/833,755, filed on Aug. 24, 2015, now abandoned.
Application No. 14/833,755 is a continuation-in-part of application No. 14/719,111, filed on May 21, 2015, now Pat. No. 10,263,131.
Application No. 14/719,111 is a continuation-in-part of application No. 14/592,519, filed on Jan. 8, 2015, now abandoned.
(60) Provisional application No. 61/976,108, filed on Apr. 7, 2014.

(51) Int. Cl. H01L 31/041; H01L 31/05; H01L 31/0735; H01L 31/0443; H01L 31/049; H01L 31/078; H01L 31/0693; H01L 31/0224

(52) U.S. Cl. CPC H01L 31/041; H01L 31/0508; H01L 31/0735; H01L 31/0443; H01L 31/049; Y02E 10/544; H01L 31/0516; H01L 31/0693; H01L 31/0504; H01L 31/022425; H01L 31/078

(57) ABSTRACT

A space-qualified solar cell assembly comprising a plurality of space-qualified solar cells mounted on a support, the support comprising a plurality of conductive vias extending from the top surface to the rear surface of the support. Each one of the pluralities of space-qualified solar cells is placed on the top surface with the first contact of a first polarity of the space-qualified solar cell electrically connected to the first conductive via. A second contact of a second polarity of each space-qualified solar cell can be connected to a second conductive via so that the first and second conductive portions form terminals of opposite conductivity type. The space-qualified solar cells on the module can be interconnected to form a string or an electrical series and/or parallel connection by suitably interconnecting the terminal pads of the vias on the back side of the module.

### 2. DESCRIPTION OF THE RELATED ART

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology. Compared to silicon, III-V compound semiconductor multijunction devices have greater energy conversion efficiencies and are generally more radiation resistance, although they tend to be more complex to properly specify and manufacture. Typical commercial III-V compound semiconductor multijunction solar cells have energy efficiencies that exceed 29.5% under one sun, air mass 0 (AM0) illumination, whereas even the most efficient silicon technologies generally reach only about 18% efficiency under comparable conditions. The higher conversion efficiency of III-V compound semiconductor solar cells compared to silicon solar cells is in part based on the ability to achieve spectral splitting of the incident radiation through the use of a plurality of series connected photovoltaic regions with different band gap energies, and accumulating the voltage at a given current from each of the regions.

Typical III-V compound semiconductor solar cells are fabricated on a semiconductor wafer in vertical, multijunction structures or stacked sequence of solar subcells, each subcell formed with appropriate semiconductor layers and including a p-n photoactive junction. Each subcell is designed to convert photons over different spectral or wavelength bands to electrical current. After the sunlight impinges on the front of the solar cell, photons pass through the subcells, with each subcell being designed for photons in a specific wavelength band. After passing through a subcell, the photons that are not absorbed and converted to electrical energy propagate to the next subcells, where such photons are intended to be captured and converted to electrical energy.

The individual solar cells or wafers are then disposed in horizontal arrays, with the individual solar cells connected together in an electrical series circuit. The shape and structure of an array, as well as the number of cells it contains, are determined in part by the desired output voltage and current needed by the payload or subcomponents of the payload, the amount of electrical storage capacity (batteries) on the spacecraft, and the power demands of the payloads during different orbital configurations.

A solar cell designed for use in a space vehicle (such as a satellite, space station, or an interplanetary mission vehicle), has a sequence of subcells with compositions and band gaps which have been optimized to achieve maximum energy conversion efficiency for the AM0 solar spectrum in space. The AM0 solar spectrum in space is notably different from the AM1.5 solar spectrum at the surface of the earth, and accordingly terrestrial solar cells are designed with subcell band gaps optimized for the AM1.5 solar spectrum.

In satellite and other space related applications, the size, mass and cost of a space vehicle or satellite power system are dependent on the power and energy conversion efficiency of the solar cells used. Putting it another way, the size of the payload and the availability of on-board services are proportional to the amount of power provided. Thus, as payloads use increasing amounts of power as they become more sophisticated, and missions and applications anticipated for five, ten, twenty or more years the power-to-weight ratio (measured in watts per kg) and lifetime efficiency of a solar cell array or panel become increasingly more important. There is increasing interest in not only the amount of power provided at initial deployment, but over the entire service life of the satellite system, or in terms of a design specification, the amount of power provided at the “end of life” (EOL) which is affected by the radiation exposure of the solar cell over time in a space environment.

Space applications frequently use high efficiency multijunction III/V compound semiconductor solar cells. Compound semiconductor solar cell wafers are often costly to produce. Thus, the waste that has conventionally been accepted in the art when cutting the rectangular solar cell out of the substantially circular solar cell wafer can imply considerable cost.

A solar cell designed for use in a space vehicle (such as a satellite, space station, or an interplanetary mission vehicle), has a sequence of subcells with compositions and band gaps which have been optimized to achieve maximum energy conversion efficiency for the AM0 solar spectrum in space. The AM0 solar spectrum in space is notably different from the AM1.5 solar spectrum at the surface of the earth, and accordingly terrestrial solar cells are designed with subcell band gaps optimized for the AM1.5 solar spectrum.

There are substantially more rigorous qualification and acceptance testing protocols used in the manufacture of space solar cells compared to terrestrial cells, to ensure that space solar cells can operate satisfactorily at the wide range of temperatures and temperature cycles encountered in space. These testing protocols include (i) high-temperature thermal vacuum bake-out; (ii) thermal cycling in vacuum (TVAC) or ambient pressure nitrogen atmosphere (APTC); and in some applications (iii) exposure to radiation equivalent to that which would be experienced in the space mission, and measuring the current and voltage produced by the cell and deriving cell performance data.

As used in this disclosure and claims, the term “space-qualified” shall mean that the electronic component (i.e., the solar cell) provides satisfactory operation under the high temperature and thermal cycling test protocols. The exemplary conditions for vacuum bake-out testing include exposure to a temperature of +100° C. to +135° C. (e.g., about +100° C., +110° C., +120° C., +125° C., +135° C.) for 2 hours to 24 hours, 48 hours, 72 hours, or 96 hours; and exemplary conditions for TVAC and/or APTC testing that include cycling between temperature extremes of −180° C. (e.g., about −180° C., −175° C., −170° C., −165° C., −150° C., −140° C., −128° C., −110° C., −100° C., −75° C., or −70° C.) to +145° C. (e.g., about +70° C., +80° C., +90° C., +100° C., +110° C., +120° C., +130° C., +135° C., or +145° C.) for 600 to 32,000 cycles (e.g., about 600, 700, 1500, 2000, 4000, 5000, 7500, 22000, 25000, or 32000 cycles), and in some space missions up to +180° C. See, for example, Fatemi et al., “Qualification and Production of Emcore ZTJ Solar Panels for Space Missions,” Photovoltaic Specialists Conference (PVSC), 2013 IEEE 39th (DOI: 10. 1109/PVSC 2013 6745052). Such rigorous testing and qualifications are not generally applicable to terrestrial solar cells and solar cell arrays.

Conventionally, such measurements are made for the AM0 spectrum for “one-sun” illumination, but for PV systems which use optical concentration elements, such measurements may be made under concentrations such as 2×, 100×, or 1000× or more.

The space solar cells and arrays experience a variety of complex environments in space missions, including the vastly different illumination levels and temperatures seen during normal earth orbiting missions, as well as even more challenging environments for deep space missions, operating at different distances from the sun, such as at 0.7, 1.0 and 3.0 AU (AU meaning astronomical units). The photovoltaic arrays also endure anomalous events from space environmental conditions, and unforeseen environmental interactions during exploration missions. Hence, electron and proton radiation exposure, collisions with space debris, and/or normal aging in the photovoltaic array and other systems could cause suboptimal operating conditions that degrade the overall power system performance, and may result in failures of one or more solar cells or array strings and consequent loss of power.

A further distinctive difference between space solar cell arrays and terrestrial solar cell arrays is that a space solar cell array utilizes welding and not soldering to provide robust electrical interconnections between the solar cells, while terrestrial solar cell arrays typically utilize solder for electrical interconnections. Welding is required in space solar cell arrays to provide the very robust electrical connections that can withstand the wide temperature ranges and temperature cycles encountered in space such as from −175° C. to +180° C. In contrast, solder joints are typically, sufficient to survive the rather narrow temperature ranges (e.g., about −40° C. to about +50° C.) encountered with terrestrial solar cell arrays.

A further distinctive difference between space solar cell arrays and terrestrial solar cell arrays is that a space solar cell array utilizes silver-plated metal material for interconnection members, while terrestrial solar cells typically utilize copper wire for interconnects. In some embodiments, the interconnection member can be, for example, a metal plate. Useful metals include, for example, molybdenum; a nickel-cobalt ferrous alloy material designed to be compatible with the thermal expansion characteristics of borosilicate glass such as that available under the trade designation KOVAR from Carpenter Technology Corporation; a nickel iron alloy material having a uniquely low coefficient of thermal expansion available under the trade designation Invar, FeNi36, or 64FeNi; or the like.

An additional distinctive difference between space solar cell arrays and terrestrial solar cell arrays is that space solar cell arrays typically utilize an aluminum honeycomb panel for a substrate or mounting platform. In some embodiments, the aluminum honeycomb panel may include a carbon composite face sheet adjoining the solar cell array. In some embodiments, the face sheet may have a coefficient of thermal expansion (CTE) that substantially matches the CTE of the bottom germanium (Ge) layer of the solar cell that is attached to the face sheet. Substantially matching the CTE of the face sheet with the CTE of the Ge layer of the solar cell can enable the array to withstand the wide temperature ranges encountered in space without the solar cells cracking, delaminating, or experiencing other defects. Such precautions are generally unnecessary in terrestrial applications.

Thus, a further distinctive difference of a space solar cell from a terrestrial solar cell is that the space solar cell must include a cover glass over the semiconductor device to provide radiation resistant shielding from particles in the space environment which could damage the semiconductor material. The cover glass is typically a ceria doped borosilicate glass which is typically, from three to six mils in thickness and attached by a transparent adhesive to the solar cell.

In summary, it is evident that the differences in design, materials, and configurations between a space-qualified III-V compound semiconductor solar cell and subassemblies and arrays of such solar cells, on the one hand, and silicon solar cells or other photovoltaic devices used in terrestrial applications, on the other hand, are so substantial that prior teachings associated with silicon or other terrestrial photovoltaic system are simply unsuitable and have no applicability to the design configuration of space-qualified solar cells and arrays. Indeed, the design and configuration of components adapted for terrestrial use with its modest temperature ranges and cycle times often teach away from the highly demanding design requirements for space-qualified solar cells and arrays and their associated components.

The assembly of individual solar cells together with electrical interconnects and the cover glass form a so-called “CIC” (Cell-Interconnected-Cover glass) assembly, which are then typically electrically connected to form an array of series-connected solar cells. The solar cells used in many arrays often have a substantial size; for example, in the case of the single standard substantially “square” solar cell trimmed from a 100 mm wafer with cropped corners, the solar cell can have a side length of seven cm or more.

The radiation hardness of a solar cell is defined as how well the cell performs after exposure to the electron or proton particle radiation which is a characteristic of the space environment. A standard metric is the ratio of the end of life performance (or efficiency) divided by the beginning of life performance (EOL/BOL) of the solar cell. The EOL performance is the cell performance parameter after exposure of that test solar cell to a given fluence of electrons or protons (which may be different for different space missions or orbits). The BOL performance is the performance parameter prior to exposure to the particle radiation.

Charged particles in space could lead to damage to solar cell structures, and in some cases, dangerously high voltage being established across individual devices or conductors in the solar array. These large voltages can lead to catastrophic electrostatic discharging (ESD) events. Traditionally for ESD protection the backside of a solar array may be painted with a conductive coating layer to ground the array to the space plasma, or one may use a honeycomb patterned metal panel which mounts the solar cells and incidentally protects the solar cells from backside radiation.

The radiation hardness of the semiconductor material of the solar cell itself is primarily dependent on a solar cell's minority carrier diffusion length (Lₘᵢₙ) in the base region of the solar cell (the term “base” region referring to the p-type base semiconductor region disposed directly adjacent to an n-type “emitter” semiconductor region, the boundary of which establishes the p-n photovoltaic junction). The less degraded the parameter Lₘᵢₙ is after exposure to particle radiation, the less the solar cell performance will be reduced. A number of strategies have been used to either improve Lₘᵢₙ, or make the solar cell less sensitive to Lₘᵢₙ reductions. Improving Lₘᵢₙ has largely involved including a gradation in dopant elements in the semiconductor base layer of the subcells so as to create an electric field to direct minority carriers to the junction of the subcell, thereby effectively increasing Lₘᵢₙ. The effectively longer Lₘᵢₙ will improve the cell performance, even after the particle radiation exposure. Making the cell less sensitive to Lunn reductions has involved increasing the optical absorption of the base layer such that thinner layers of the base can be used to absorb the same amount of incoming optical radiation.

Another consideration in connection with the manufacture of space solar cell arrays is that conventionally, solar cells have been arranged on a support and interconnected using a substantial amount of manual labor. For example, first individual CICs are produced with each interconnect individually welded to the solar cell, and each cover glass individually mounted.

Then, these CICs are connected in series to form strings, generally in a substantially manual manner, including the welding steps from CIC to CIC. Then, these strings are applied to a panel substrate and electrically interconnected in a process that includes the application of adhesive, wiring, etc. All of this has traditionally been carried out in a manual and substantially artisanal manner.

The energy conversion efficiency of multijunction solar cells is affected by such factors as the number of subcells, the thickness of each subcell, the composition and doping of each active layer in a subcell, and the consequential band structure, electron energy levels, conduction, and absorption of each subcell, as well as the effect of its exposure to radiation in the ambient environment over time. The identification and specification of such design parameters is a non-trivial engineering undertaking, and would vary depending upon the specific space mission and customer design requirements. Since the power output is a function of both the voltage and the current produced by a subcell, a simplistic view may seek to maximize both parameters in a subcell by increasing a constituent element, or the doping level, to achieve that effect. However, in reality, changing a material parameter that increases the voltage may result in a decrease in current, and therefore a lower power output. Such material design parameters are interdependent and interact in complex and often unpredictable ways, and for that reason are not “result effective” variables that those skilled in the art confronted with complex design specifications and practical operational considerations can easily adjust to optimize performance.

Moreover, the current (or more precisely, the short circuit current density J_{sc}) and the voltage (or more precisely, the open circuit voltage V_{oc}) are not the only factors that determine the power output of a solar cell. In addition to the power being a function of the short circuit density (J_{sc}), and the open circuit voltage (V_{oc}), the output power is actually computed as the product of V_{oc} and J_{sc}, and a Fill Factor (FF). As might be anticipated, the Fill Factor parameter is not a constant, but in fact may vary at a value between 0.5 and somewhat over 0.85 for different arrangements of elemental compositions, subcell thickness, and the dopant level and profile. Although the various electrical contributions to the Fill Factor such as series resistance, shunt resistance, and ideality (a measure of how closely the semiconductor diode follows the ideal diode equation) may be theoretically understood, from a practical perspective the actual Fill Factor of a given subcell cannot always be predicted, and the effect of making an incremental change in composition or band gap of a layer may have unanticipated consequences and effects on the solar subcell semiconductor material, and therefore an unrecognized or unappreciated effect on the Fill Factor. Stated another way, an attempt to maximize power by varying a composition of a subcell layer to increase the V_{oc} or J_{sc} or both of that subcell, may in fact not result in high power, since although the product V_{oc} and J_{sc} may increase, the FF may decrease and the resulting power also decrease. Thus, the V_{oc} and J_{sc} parameters, either alone or in combination, are not necessarily “result effective” variables that those skilled in the art confronted with complex design specifications and practical operational considerations can easily adjust to optimize performance.

Furthermore, the fact that the short circuit current density (J_{sc}), the open circuit voltage (V_{oc}), and the fill factor (FF), are affected by the slightest change in such design variables, the purity or quality of the chemical pre-cursors, or the specific process flow and fabrication equipment used, and such considerations further complicates the proper specification of design parameters and predicting the efficiency of a proposed design which may appear “on paper” to be advantageous.

It must be further emphasized that in addition to process and equipment variability, the “fine tuning” of minute changes in the composition, band gaps, thickness, and doping of every layer in the arrangement has critical effect on electrical properties such as the open circuit voltage (V_{oc}) and ultimately on the power output and efficiency of the solar cell.

To illustrate the practical effect, consider a design change that results in a small change in the V_{oc} of an active layer in the amount of 0.01 volts, for example changing the V_{oc} from 2.72 to 2.73 volts. Assuming all else is equal and does not change, such a relatively small incremental increase in voltage would typically result in an increase of solar cell efficiency from 29.73% to 29.84% for a triple junction solar cell, which would be regarded as a substantial and significant improvement that would justify implementation of such design change.

For a single junction GaAs subcell in a triple junction device, a change in V_{oc} from 1.00 to 1.01 volts (everything else being the same) would increase the efficiency of that junction from 10.29% to 10.39%, about a 1% relative increase. If it were a single junction stand-alone solar cell, the efficiency would go from 20.58% to 20.78%, still about a 1% relative improvement in efficiency.

Present day commercial production processes are able to define and establish band gap values of epitaxially deposited layers as precisely as 0.01 eV, so such “fine tuning” of compositions and consequential open circuit voltage results are well within the range of operational production specifications for commercial products.

Another important mechanical or structural consideration in the choice of semiconductor layers for a solar cell is the desirability of the adjacent layers of semiconductor materials in the solar cell, i.e. each layer of crystalline semiconductor material that is deposited and grown to form a solar subcell, have similar or substantially similar crystal lattice constants or parameters.

Here again there are trade-offs between including specific elements in the composition of a layer which may result in improved voltage associated with such subcell and therefore potentially a greater power output, and deviation from exact crystal lattice matching with adjoining layers as a consequence of including such elements in the layer which may result in a higher probability of defects, and therefore lower manufacturing yield.

In that connection, it should be noted that there is no strict definition of what is understood to mean two adjacent layers are “lattice matched” or “lattice mismatched”. For purposes in this disclosure, “lattice mismatched” refers to two adjacently disposed materials or layers (with thicknesses of greater than 100 nm) having in-plane lattice constants of the materials in their fully relaxed state differing from one another by less than 0.02% in lattice constant. (Applicant notes that this definition is considerably more stringent than that proposed, for example, in U.S. Pat. No. 8,962,993, which suggests less than 0.6% lattice constant difference as defining “lattice mismatched” layers).

Solar cells are often produced from circular or substantially circular wafers sometimes 100 mm or 150 mm in diameter. Large solar cells (i.e. with, for example, an area from 25 to 60 cm² representing one-quarter or more of the area of the wafer) are conventionally preferred so as to minimize the costs associated with the assembly of the solar cells onto a support to form a solar cell module. However, the use of large solar cells results in poor wafer utilization, and large solar cells often present issues of defects or variation in the material quality across the surface of the wafer. Also, larger solar cells are fragile and present handling challenges during subsequent fabrication steps that result in breakage of the wafer or solar cells and corresponding lower manufacturing yield. Moreover, large solar cells of predetermined size cannot be easily or efficiently accommodated on panels of arbitrary aspect ratios and configurations which may vary depending upon the “wing” configuration of the satellite or space vehicle. Also, large solar cells are rigidnd can sometimes be problematic in terms of meeting requirements for flexibility of the solar cell assembly or solar array panel. Sometimes, flexibility is desired so that the solar cell assembly or the solar array panel can be bent or rolled, for example, so that it is displaceable between a stowed position in which it is wound around a mandrel or similar, and a deployed position extending outward from, for example, a space vehicle so as to permit the solar cells to receive sunlight over a substantial area. Sometimes, large solar cells can be problematic from the perspective of providing a flexible assembly or panel that can be readily bent, wound, etc. without damage to the solar cells and their interconnections.

It is possible to reduce the amount of waste by dividing a circular or substantially circular wafer not into one or two single cells, but into a large number of smaller cells. By dividing a circular or substantially circular wafer into a large amount of relatively small cells, most of the wafer surface can be used to produce solar cells, and the waste is reduced. For example, a solar cell wafer having a diameter of 100 mm or 150 mm and a surface area in the order of 80 cm² or 180 cm² can be used to produce a large amount of small solar cells, such as square or rectangular solar cells, each having a surface area of less than 5 cm², or in some embodiments less than 1 cm², less than 0.1 cm², less than 0.05 cm², or less than 0.01 cm². For example, substantially rectangular—such as square—solar cells can be obtained in which the sides are less than 10, 5, 3, 2, 1 or even 0.5 mm long. Thereby, the amount of waste of wafer material can be substantially reduced, and at the same time high utilization of the wafer surface can be obtained. Also, when dividing a solar cell wafer into a relatively large number of solar cells, solar cells obtained from a more or less defective region of the wafer can be discarded, or “binned” as lower performance solar cells, that is, not used for the manufacture of the solar cell assemblies. Thus, a relatively high quality of the solar cell assemblies in terms of performance of the solar cells can be achieved, while the amount of waste is kept relatively low.

However, the use of a large number of relatively small solar cell involves the drawback that for a given effective surface area of the final solar cell assembly or solar array panel, there is an increased number of interconnections between solar cells, in a parallel and/or in series, which may render the process of manufacturing the solar cell assembly or the panel more complex and/or expensive, and which may also render the entire circuit less reliable, due to the risk for low reliability, low yield, or other manufacturing difficulties or errors due to defective or less-than-ideal interconnections between individual solar cells.

### SUMMARY OF THE DISCLOSURE

### 1. Objects of the Disclosure

It is an object of the present invention to provide an improved multijunction solar cell assembly or module comprising a plurality of solar cells.

It is an object of the present invention to provide a platform or substrate for the series and/or parallel connection of discrete groups of solar cells.

It is an object of the present invention to provide a lightweight solar cell assembly or module that is suitable for automated manufacturing processes.

It is another object of the invention to provide a flexible solar cell array module with high W/kg and W/m² and low cost.

It is another object of the invention to provide a solar cell assembly or module that utilizes an array of small solar cells, for example, solar cells each having a surface area of less than 5 cm², or in some embodiments less than 1 cm², less than 0.1 cm², less than 0.05 cm², or less than 0.01 cm², for example, substantially rectangular—such as square—solar cells in which the (longest) sides are less than 10, 5, 3, 2, 1 or even 0.5 mm long.

It is another object of the invention to provide for methods for producing solar cell assemblies or modules.

It is another object of the invention to provide for a solar array panel comprising a plurality of interconnected modules, and methods for producing a solar array panel.

Some implementations or embodiments may achieve fewer than all of the foregoing objects.

### 2. Features of the Disclosure

Briefly, and in general terms, the present disclosure provides a space-qualified solar cell assembly designed for operation at AM0 and at a 1 MeV electron equivalent fluence of at least 5×10¹⁴ e/cm², the assembly comprising a III-V compound semiconductor multijunction solar cell including at least three subcells, including a ceria doped borosilicate glass supporting member that is 3 to 6 mils in thickness attached to each solar cell with a transparent adhesive, wherein a combination of compositions and band gaps of the subcells is designed to maximize efficiency of the solar cell at a predetermined time, after initial deployment when the solar cell is deployed in space at AM0 and at an operational temperature in the range of 40 to 70 degrees Centigrade, the predetermined time being at least five years and referred to as the end-of-life (EOL), the space-qualified solar cell assembly comprising: a support comprising a first side and an opposing second side; a first conductive layer comprising first and second spaced-apart conductive portions disposed on the second side of the support; a plurality of solar cells mounted on the first side of the support, each solar cell of the plurality of solar cells comprising a top surface including a contact of a first polarity type, and a rear surface including a contact of a second polarity type; a plurality of first vias in the support extending from the first side of the support to the second side of the support; a plurality of second vias in the support extending from the first side of the support to the second side of the support; a plurality of first conductive interconnects extending from the first side of the support to the first conductive portion of the first conductive layer, each respective interconnect making electrical contact with the contact of the first polarity type of a respective solar cell and extending through a respective one of the first vias to make electrical contact with the first conductive portion of the first conductive layer disposed on the second side of the support; a plurality of second conductive interconnects extending from the first side of the support to the second conductive portion of the first conductive layer, each respective interconnect making electrical contact with the contact of the second polarity type of a respective solar cell and extending through a respective one of the second vias to make electrical contact with the second conductive portion of the first conductive layer disposed on the second side of the support; and a first terminal of the module of a first polarity type disposed on the second side of the support and connected to the first conductive portion of the second conductive layer; a second terminal of the module of a second polarity type disposed on the second side of the support and connected to the second conductive portion of the second conductive layer.

In some embodiments, the first conductive portion of the first conductive layer comprises a plurality of parallel strips of equal width, and the second conductive portion comprises a plurality of parallel strips of equal width, with the parallel strips of the first and second portions being interdigitated.

In some embodiments the solar cell assembly further comprises a second conductive layer comprising spaced-apart conductive portions disposed on the first side of the support, with each of the solar cells mounted on a respective one of the conductive portions, and wherein the first and second conductive portions of the first conductive layer and the spaced-apart conductive portions of the second conducive layer, have a thickness in the range of 5 to 50 microns.

In some embodiments, the first and second conductive interconnect comprises an electroplated metal conductor extending from the surface of the first side of the support to the respective first and second conductive portions of the first conductive layer.

In some embodiments the solar cell assembly further comprises a first set of interconnect wires, each wire extending from a contact of first polarity of each solar cell to a respective metal conductor on the surface of the first side of the support, and a second set of interconnect wires, each wire extending from a contact of second polarity of each solar cell to a respective metal conductor on the surface of the first side of the support.

In some embodiments, the plurality of solar cells disposed on the support are electrically connected in parallel.

In some embodiments the plurality of solar cells are disposed adjacent to one another are electrically connected in series.

In some embodiments, a first set of the plurality of solar cells disposed on the support are electrically connected in parallel, and a second set of the plurality of solar cells on the support are connected in electrical series.

In some embodiments, the support is flexible and is composed of a poly (4,4′-oxydiphenylene-pyromellitimide) material.

In some embodiments, each of the conductive interconnects comprises a single conductive element extending from the contact on the solar cell to the first or second conductive portions on the second side of the support through the via.

In some embodiments, each via has a diameter of between 100 and 200 microns.

In some embodiments, the first terminal of the module is disposed on a first peripheral edge of the module and connected to the first conductive portion of the first conductive layer.

In some embodiments, the second terminal of the module is disposed on a second peripheral edge of the module extending parallel to the first peripheral edge of the module, and connected to the second conductive portion of the first conductive layer.

In some embodiments there further comprises a bypass diode mounted in parallel with the solar cells and functioning as a bypass diode of the entire solar cell assembly.

In some embodiments, the bypass diode has a top terminal of a first conductivity type and a bottom terminal of a second conductivity type, and the bottom terminal is mounted on and electrically connected to the first conductive layer.

In some embodiments, the vias are arranged between the adjacent strips of the first and second conductive portions.

In some embodiments, the assembly further comprises a bypass diode which can be mounted on, for example, any of the first and second surfaces and function as a bypass diode for the entire solar cell assembly or subportions or groups of solar cells thereof. Bypass diodes are frequently used in solar cell assemblies comprising a plurality of series connected solar cells or groups of solar cells. One reason for the use of bypass diodes is that if one of the solar cells or groups of solar cells is shaded or damaged, current produced by other solar cells, such as by unshaded or undamaged solar cells or groups of solar cells, can flow through the by-pass diode and thus avoid the high resistance of the shaded or damaged solar cell or group of solar cells.

The bypass diodes can be mounted on one of the conductive layers and comprise an anode terminal and a cathode terminal. The diode can be electrically coupled in parallel with the semiconductor solar cells and configured to be reverse-biased when the semiconductor solar cells generate an output voltage at or above a threshold voltage, and configured to be forward-biased when the semiconductor solar cells generate an output voltage below the threshold voltage. Thus, when the solar cell assembly is connected in series with other solar cell assemblies, the bypass diode can serve to minimize the deterioration of performance of the entire string of solar cell assemblies when one of the solar cell assemblies is damaged or shaded.

In another aspect, the present disclosure provides a method of manufacturing a solar cell assembly comprising: a support comprising a first side and an opposing second side; a first conductive layer comprising first and second spaced-apart conductive portions disposed on the second side of the support; a plurality of solar cells mounted on the first side of the support, each solar cell of the plurality of solar cells comprising a top surface including a contact of a first polarity type, and a rear surface including a contact of a second polarity type; a plurality of first vias in the support extending from the first side of the support to the second side of the support; a plurality of second vias in the support extending from the first side of the support to the second side of the support; a plurality of first conductive interconnects extending from the first side of the support to the first conductive portion of the first conductive layer, each respective interconnect making electrical contact with the contact of the first polarity type of a respective solar cell and extending through a respective one of the first vias to make electrical contact with the first conductive portion of the first conductive layer disposed on the second side of the support; a plurality of second conductive interconnects extending from the first side of the support to the second conductive portion of the first conductive layer, each respective interconnect making electrical contact with the contact of the second polarity type of a respective solar cell and extending through a respective one of the second vias to make electrical contact with the second conductive portion of the first conductive layer disposed on the second side of the support; and a first terminal of the module of a first polarity type disposed on the second side of the support and connected to the first conductive portion of the second conductive layer; a second terminal of the module of a second polarity type disposed on the second side of the support and connected to the second conductive portion of the second conductive layer.

In some embodiments, a plurality of solar cells are mounted on the first side of the support, each solar cell of the plurality of solar cells comprising a top surface including a contact of a first polarity type (such as a cathode contact in embodiments in which the solar cell is an n-on-p configuration), and a rear surface including a contact of a second polarity type (such as an anode contact in embodiments in which the solar cell is an n-on-p configuration).

In some embodiments, a plurality of vias in the support are provided extending from the first side of the support to the second side of the support, and a plurality of conductive interconnects are provided extending from the first side of the support to the second side of the support, each respective interconnect making electrical contact with the contact of the first polarity type of a respective solar cell and extending through a respective via to make electrical contact with a conductive layer disposed on the second side of the support.

In some embodiments, the first conductive portion comprises a plurality of parallel strips on the rear surface. In other embodiments of the invention, the second conductive portion comprises a plurality of strips having a width that varies along the strip, for example, a width that increases from a free end of the strip to an end of the strip where the strip is electrically connected to the first terminal. For example, the strips can have a substantially triangular configuration.

A reason for the use of strips having a width that varies along the strip on either the top or the rear surface is that when current flows in one direction, such as from a free end of the strip towards an end of the strip where the strip is connected to the terminal, the amount of current increases along the strip, as more and more solar cells mounted on the strip are connected in electrical series, and contribute to the total current flowing in the strip. Thus, the closer one gets to the end of the strip where the strip is connected to the terminal, the higher the need for a substantial cross section of the conductive material in order to carry the current and avoid overheating or excessive losses. Thus, varying the width of the strips and thus the cross-sectional area of the conductive material in accordance with the increase in current, optimizes the use of conductive material and thus implies a saving in terms of weight, which is important especially in space applications.

In some embodiments, the first conductive portion is a metallic layer that has a thickness in the range of 5 to 50 microns.

In some embodiments, a plurality of solar cells are disposed closely adjacent to one another on each of the strips, separated by a distance of between 5 and 25 microns.

In some embodiments, each of the solar cells have a dimension in the range of 0.5 to 10 mm on a side.

In some embodiments, the support is a polyimide film having a thickness of between 25 and 100 microns.

In some embodiments, the via has a diameter of between 100 and 200 microns.

In some embodiments, the first terminal of the module is disposed on a first peripheral edge of the module.

In some embodiments, the second terminal of the module is composed of a metallic strip extending parallel to the first peripheral edge of the module.

In some embodiments of the disclosure, the first terminal and the second terminal are arranged in correspondence with opposite peripheral edges of the support.

The arrangement of the present disclosure makes it possible to connect a plurality of assemblies in series by arranging the assemblies one after the other in a partly overlapping manner, for example, in a way similar to the way in which roofing tiles are arranged on a roof, so that the second terminal of one of the assemblies contacts the first terminal of another one of the assemblies. This provides for easy electrical and mechanical interconnection without any use of discrete, complex interconnect elements, and the laborious welding or soldering of the interconnect elements to the terminals. In some embodiments, both terminals are on the bottom side of the assembly, and a cut-out in one side of the assembly makes access possible from an overlying assembly to the bottom terminal. The terminals of adjacent assemblies can be directly placed in contact with each other and attached using suitable bonding means, such as soldering or welding.

In some embodiments, the bypass diode has a top terminal of a first polarity type and a bottom terminal of a second polarity type, and the bottom terminal is mounted on and electrically connected to the first conductive layer.

In some embodiments of the disclosure, at least the first conductive portion comprises a plurality of strips, wherein said vias are arranged between adjacent strips. The solar cells can thus be arranged on the strips, for example, with one or two rows of solar cells on each strip, and interconnects such as simple wires, such as wire bonded wires, can pass from the solar cells to the second conductive portion through vias arranged in rows parallel with said rows of solar cells, and arranged between the strips. In some embodiments of the disclosure, the strips have one free end and another end where the strips are connected to the terminal.

In some embodiments, the assembly is an array of between 9 and 36 solar cells.

In some embodiments, the solar cells are multijunction III/V compound semiconductor solar cells.

It has been found that this arrangement is practical and appropriate for automated manufacturing processes. The solar cells can be tightly packed adjacent to one another at one side of the support, whereas the other side of the support is used as a conductive backplane to provide an electrical element that connects some or all of the solar cells in parallel. Also, in some embodiments, the presence of terminals on both sides of the support facilitates interconnection and integration of the assemblies or modules into a solar array panel in a simply and highly coordinated manner and without need for special or discrete interconnects between the different modules. For example, a series of said solar cell modules or assemblies can be arranged in a row with the second terminal of one of the solar cell modules overlapping with and being bonded to the first terminal of a preceding solar cell module, etc. Thus, a simple and reliable mechanical and electrical series connection of solar cell modules can be established.

In another aspect, the present disclosure provides a solar array panel comprising a plurality of modular solar cell assemblies, each solar cell assembly including a solar cell assembly comprising: a support comprising a first side and an opposing second side; a first conductive layer comprising first and second spaced-apart conductive portions disposed on the second side of the support; a plurality of solar cells mounted on the first side of the support, each solar cell of the plurality of solar cells comprising a top surface including a contact of a first polarity type, and a rear surface including a contact of a second polarity type; a plurality of first vias in the support extending from the first side of the support to the second side of the support; a plurality of second vias in the support extending from the first side of the support to the second side of the support; a plurality of first conductive interconnects extending from the first side of the support to the first conductive portion of the first conductive layer, each respective interconnect making electrical contact with the contact of the first polarity type of a respective solar cell and extending through a respective one of the first vias to make electrical contact with the first conductive portion of the first conductive layer disposed on the second side of the support; a plurality of second conductive interconnects extending from the first side of the support to the second conductive portion of the first conductive layer, each respective interconnect making electrical contact with the contact of the second polarity type of a respective solar cell and extending through a respective one of the second vias to make electrical contact with the second conductive portion of the first conductive layer disposed on the second side of the support; and a first terminal of the module of a first polarity type disposed on the second side of the support and connected to the first conductive portion of the second conductive layer; a second terminal of the module of a second polarity type disposed on the second side of the support and connected to the second conductive portion of the second conductive layer.

In another aspect, the present disclosure provides a space vehicle and its method of fabrication comprising: a payload disposed on or within the space vehicle; and a power source for the payload, including an array of solar cell assemblies mounted on a panel, each solar cell assembly including an array of solar cells as described in any of the described embodiments.

In another aspect, the present disclosure provides a solar cell assembly that comprises a plurality of solar cells and a support, the support comprising a conductive layer, such as a metal layer, comprising a first conductive portion. Each solar cell of said plurality of solar cells comprises a top or front surface and a bottom or rear surface and a bottom contact in correspondence with said rear surface. Each solar cell is placed on the first conductive portion with the bottom contact electrically connected to the first conductive portion so that the plurality of solar cells are connected in parallel through the first conductive portion. In the present disclosure, the term solar cell refers to a discrete solar cell semiconductor device or chip.

In another aspect, the present disclosure provides a method of manufacturing a solar cell assembly having between 16 and 100 solar cells, in which the solar cells are positioned and placed on a support in an automated manner by machine vision and a pick and place assembly tool.

In another aspect, the present disclosure provides a method of manufacturing a solar cell assembly having between 16 and 100 solar cells, in which the solar cells are positioned and placed on a first conductive portion of a support, so that the solar cells can make up a substantial part of the upper surface of the support, such as more than 50%, 70%, 80%, 90%, 95% or more of the total surface of the support.

In another aspect, the present disclosure provides a method of manufacturing a solar cell assembly having between 16 and 100 solar cells, in which the solar cells are positioned and placed on a conductive portion of a support, so that the contact or contacts at the rear surface of each solar cell are electrically connected on either (i) the top side of the support, or (ii) the bottom side of the support, or (iii) both (i) and (ii), which thus serves to interconnect the solar cells in parallel.

In some embodiments, the connection between the bottom contact of each solar cell and the first conductive portion of the metal layer of the support can be direct and/or through a conductive bonding material. Thus, this approach is practical for creating solar cell assemblies of a large amount of relatively small solar cells, such as solar cells obtained by dividing a solar cell wafer having a substantially circular shape into a large number of individual solar cells having a substantially rectangular shape, for enhanced wafer utilization. The first conductive portion is continuous and thus acts as a bus interconnecting the bottom contacts of the solar cells. In addition, the conductive layer, including the first conductive portion, can act as a thermal sink for the solar cells.

In some embodiments of the disclosure, the first conductive portion and the second conductive portion are interconnected by means of at least one bypass diode. A bypass diode functions for routing electrical current around the solar cells. Bypass diodes are frequently used in solar cell assemblies comprising a plurality of series connected solar cells or groups of solar cells. If one of the solar cells or groups of solar cells is shaded or damaged, current produced by other solar cells, such as by unshaded or undamaged solar cells or groups of solar cells, can flow through the bypass diode and thus avoid the high resistance of the shaded or damaged solar cell or group of solar cells. The diodes can be mounted on the top side of the metal layer and comprise an anode terminal and a cathode terminal, with one terminal connected to the metal layer.

The diode can be electrically coupled in parallel with the semiconductor solar cells and configured to be reverse-biased when the semiconductor solar cells generate an output voltage at or above a threshold voltage, and configured to be forward-biased when the semiconductor solar cells generate an output voltage below the threshold voltage.

In some embodiments of the disclosure, said at least one diode comprises a top side terminal and a rear side terminal, the diode being placed on the second conductive portion with said rear side terminal of the diode electrically coupled to the second conductive portion, the top side terminal of the diode being electrically coupled to the first conductive portion, for example, through a via in a support or core separating the first conductive portion from the second conductive portion. In an alternative embodiment of the disclosure, the diode can be placed on the first conductive portion with the rear side terminal of the diode being electrically coupled to the first conductive portion, the top side terminal of the diode being electrically coupled to the second conductive portion. Both alternatives are possible, but it may sometimes be preferred to use the first conductive portion to support the solar cells, and the second conductive portion to support the diode or diodes. In other embodiments, it can be preferred to have both the diode and the solar cells arranged on the same conductive portion, for example, on the same side of a support having the first conductive portion on one side and the second conductive portion on another side. Having all the solar cell and diode components on the same side of the support may sometimes serve to simplify the assembly process.

In some embodiments of the disclosure, the solar cell assembly comprises a plurality of rows of solar cells placed on the first conductive portion, each row of solar cells being connected to a subportion, such as a strip, of the second conductive portion, through vias arranged in rows extending in parallel with the solar cells.

In some embodiments of the disclosure, each solar cell has a surface area of less than 1 cm². The approach of the disclosure can be especially advantageous in the case of relatively small solar cells, such as solar cells having a surface area of less than 1 cm², less than 0.1 cm² or even less than 0.05 cm² or 0.01 cm². For example, substantially rectangular—such as square-solar cells can be obtained in which the sides are less than 10, 5, 3, 2, 1 or even 0.5 mm long.

This makes it possible to obtain rectangular solar cells out of a substantially circular wafer with reduced waste of wafer material, and the approach of the disclosure makes it possible to easily place and interconnect a large number of said solar cells in a parallel, so that they, in combination, perform as a larger solar cell.

In some embodiments of the disclosure, each solar cell is bonded to the first conductive portion by a conductive bonding material. Using a conductive bonding material makes it possible to establish the connection between a bottom contact of each solar cell and the support by simply bonding the solar cell to the support using the conductive bonding material. The conductive bonding material can be selected to enhance heat transfer between solar cell and support.

In some embodiments of the disclosure, the conductive bonding material is an indium alloy. Indium alloys have been found to be useful and advantageous, in that the indium can make the bonding material ductile, thereby allowing the use of the bonding material spread over a filial part of the surface of the support without making the support substantially more rigid and reducing the risk of formation of cracks when the assembly is subjected to bending forces. Preferably, support, solar cells and bonding material are matched to each other to feature, for example, similar thermal expansion characteristics. On the other hand, the use of a metal alloy, such as an indium alloy, is advantageous over other bonding material such as polymeric adhesives in that it allows for efficient heat dissipation into the underlying conductive layer, such as for example a copper layer. In some embodiments of the disclosure, the bonding material is indium lead.

In some embodiments of the disclosure, the conductive layer comprises copper.

In some embodiments of the disclosure, the support comprises a KAPTON® film, the conductive layer being placed on the KAPTON® film. The option of using a KAPTON® film for the support is practical for, for example, space applications. KAPTON® is a trademark of E.I. du Pont de Nemours and Company. The chemical name for KAPTON® is poly (4,4′-oxydiphenylene-pyromellitimide). Other polyimide film sheets or layers may also be used.

In some embodiments of the disclosure, the contact of the second polarity type of each solar cell comprises a conductive, such as a metal, layer extending over a substantial portion of the rear surface of the respective solar cell, preferably over more than 50% of the rear surface of the respective solar cell, more preferably over more than 90% of the rear surface of the respective solar cell. In some embodiments of the disclosure, the contact of the second polarity type comprises a conductive, such as a metal, layer covering the entire rear surface of the solar cell. This helps to establish a good and reliable contact with the conductive portion of the conductive layer of the support.

In some embodiments of the disclosure, each solar cell comprises at least one III-V compound semiconductor subcell. As indicated above, high wafer utilization can be especially advantageous when the solar cells are high efficiency solar cells such as III-V compound semiconductor solar cells, often implying the use of relatively expensive wafer material.

In some embodiments of the disclosure, the solar cell assembly has a substantially rectangular shape and a surface area in the range of 25 to 400 cm².

Another aspect of the disclosure relates to a solar array panel comprising a plurality of solar cell assemblies, each of these solar cell assemblies comprising a solar cell assembly according to one of the previously described aspects of the disclosure. As indicated above, the solar cell assemblies can advantageously serve as sub-assemblies which can be interconnected to form a major solar array panel, comprising, for example, an array of solar cell assemblies comprising a plurality of strings of such solar cell assemblies, each string comprising a plurality of solar cell assemblies connected in series. Thus, a modular approach can be used for the manufacture of relatively large solar array panels out of small solar cells, which are assembled to form assemblies as described above, whereafter the assemblies or modules are interconnected to form a panel.

In some embodiments of the disclosure, the step of providing a plurality of solar cells comprises obtaining a plurality of substantially rectangular solar cells, such as square solar cells, out of a substantially circular wafer. In some embodiments of the disclosure, each of said solar cells has a surface area of less than 1 cm². The approach of the disclosure can be especially advantageous in the case of relatively small solar cells, such as solar cells having a surface area of less than 1 cm², less than 0.1 cm² or even less than 0.05 cm² or 0.01 cm². For example, substantially rectangular—such as square—solar cells can be obtained in which the sides are less than 10, 5, 3, 2, 1 or even 0.5 mm long. This makes it possible to obtain rectangular solar cells out of a substantially circular wafer with a small waste of wafer material, whereas the approach of the disclosure makes it possible to easily place an interconnect a large number of said solar cells in parallel, so that they, in combination, perform as a larger solar cell.

In some embodiments of the disclosure, the method comprises removing conductive material on the first side of the support so as to establish a plurality of conductive strips. In some embodiment of the disclosure, the vias are arranged adjacent to the strips, for example, between adjacent strips. In some embodiments of the disclosure, the strips are given a shape, such as a substantially triangular shape, so that the width of the strip increases from a free end of the strip to a terminal end where the strip is electrically connected to other strips. This arrangement can sometimes be preferred to optimize the use of conductive material and minimize weight. In other embodiments of the disclosure, the strips have constant width.

In some embodiments of the disclosure, the method comprises removing conductive material on the second side of the support so as to establish a plurality of conductive strips. In some embodiment of the disclosure, the vias are arranged adjacent to the strips, for example, between adjacent strips. In some embodiments of the disclosure, the strips are given a shape, such as a substantially triangular shape, so that the width of the strip increases from a free end of the strip to a terminal end where the strip is electrically connected to other strips. This arrangement can sometimes be preferred to optimize the use of conductive material and minimize weight. In other embodiments of the disclosure, the strips have constant width. In some embodiments of the disclosure, the removal of conductive material is carried out so that conductive strips are established having one free and being connected to each other at an opposite end.

In some embodiments of the invention, the method comprises the step of providing a second terminal on the first side of the support and a first terminal on the second side of the support, the first terminal comprising a portion of the second conductive layer extending adjacent a first edge of the support, and the second terminal comprising a portion of the first conductive layer extending adjacent to a second edge of the support, parallel with the first edge of the support. This can facilitate the interconnection of a plurality of assemblies in series when, for example, fabricating a solar array panel. For example, in some embodiments of the invention, the support is substantially rectangular and one solar cell assembly can be placed partially overlapping another one in correspondence with an edge, so that the first terminal of a second one of the solar cell assemblies is placed on top of the second terminal of the first solar cell assembly. Thereby, firm and reliable bonding and interconnection can be established without the use of any additional interconnects: the bonding can take place directly, using, for example, a suitable conductive soldering or welding material, such as an indium alloy, to attach the respective first and second terminals to each other. Thereby, a series of modules can be interconnected in series in a simple and reliable manner, so that a desired output voltage is obtained, and each solar cell assembly includes a substantial amount of solar cells connected in parallel, so as to establish a desired level of output current.

In some embodiments of the disclosure, the method comprises the step of providing a bypass diode on the assembly, in parallel with the solar cells. In some embodiments of the disclosure, the bypass diode is mounted on the first conductive layer and connected to the second conductive layer through a via in the support, and in other embodiments of the disclosure the bypass diode is mounted on the second conductive layer and connected to the first conductive layer through a via in the support. In some embodiments, more than one bypass diode is provided on each solar cell assembly.

In some embodiments of the disclosure, the method comprises the step of obtaining at least a plurality of the solar cells by dividing, for example cutting, at least one solar cell wafer into at least 10 substantially square or rectangular solar cells, such as into at least 100 or into at least 500 solar cells or more. In some embodiments of the disclosure, after dividing said at least one solar cell wafer into a plurality of substantially square or rectangular solar cells, some of said solar cells are selected so as not to be used for producing the solar cell assembly; the solar cells selected not to be used for producing the solar cell assembly may correspond to a defective region of the solar cell wafer. Thereby, overall efficiency of the solar cell assembly is enhanced.

In some embodiments of the disclosure, the solar cells have a surface area of less than 5 cm², or in some embodiments less than 1 cm², less than 0.1 cm², less than 0.05 cm², or less than 0.01 cm². For example, substantially rectangular—such as square—solar cells can be obtained in which the sides are less than 10, 5, 3, 2, 1 or even 0.5 mm long.

In some embodiments of the disclosure, the conductive interconnects are wires, and in some embodiments of the disclosure the method comprises wire ball bonding the wires to the contacts of the solar cell of first and second polarity type and/or to the contact pads of the vias.

In some embodiments of the disclosure, the solar cells are III-V compound semiconductor multijunction solar cells. Such solar cells feature high efficiency but are relatively costly to manufacture. Thus, the reduced waste obtained by subdividing wafers into small solar cells is beneficial from a cost perspective. Also, the use of small solar cells can be advantageous to enhance flexibility of the solar cell assemblies

In some embodiments of the disclosure, the solar cells are attached to the first conductive layer using a conductive bonding material, for example, an indium alloy. Advantages involved with the use of an indium alloy have been explained above.

A further aspect of the disclosure relates to a solar array panel comprising a plurality of solar cell assemblies including at least a first solar cell assembly and a second solar cell assembly, each solar cell assembly comprising a support having a first side and an opposing second side, with a first conductive layer disposed on the first side of the support and a second conductive layer disposed on the second side of the support, and a plurality of solar cells mounted on the first side of the support; wherein the first solar cell assembly and the second solar cell assembly are connected in series, wherein the second solar cell assembly partially overlaps with the first solar cell assembly so that a portion of the second conductive layer of the second solar cell assembly overlaps with and is bonded to a portion of the first conductive layer of the first solar cell assembly. Thus, electrical series connection between the first solar cell assembly and the second solar cell assembly can be established by bonding the respective second and first layers to each other where the assemblies overlap. Thus, a direct and reliable connection can be established, without need for any additional interconnects. Two or more, such as three, four, five, ten, or more modules or assemblies can be connected in series, and the connections can be established without use of additional and/or complex interconnects. The direct connection can serve to simplify the manufacturing and facilitate automation thereof. In addition, as the interconnection can be established at a plurality of points along and across the overlapping portions, and/or over a substantial portion of the overlapping surface, the interconnection can be established in a very reliable manner, using welding or soldering techniques and, if desired, additional conductive bonding material that is placed between the overlapping portions and melted during the welding or soldering process. In some embodiments of the invention, an indium alloy can be used as a bonding material. Thus, solar cell assemblies or modules can be placed one after the other so as to form a solar array panel comprising a plurality of said solar cell assemblies, arranged in one or more strings of series connected solar cell assemblies, the solar cell assemblies within each string partly overlapping with each other, in a manner resembling the manner in which tiles are often arranged on the roofs of buildings, etc.

In some embodiments of the disclosure, the solar cell assemblies are flexible. Thus, when the solar cell assemblies are arranged on a substrate with a second solar cell assembly partly overlapping with a first solar cell assembly, the second solar cell assembly can, due to its flexibility, adapt so that part of it extends in parallel with the first solar cell assembly, that is, along a top surface of the substrate, whereas another part of it is curved so that it extends upwards from the substrate in the vicinity of an edge of the first solar cell assembly, and overlies a portion of the first solar cell assembly in the vicinity of said edge. Thus, in some embodiments of the disclosure, the solar cell assemblies are placed so that at least a second solar cell assembly partially overlaps at least a first solar cell assembly, whereby the second solar cell assembly adapts it shape accordingly, whereby part of the second solar cell assembly and at least part of the first solar cell assembly are arranged in one plane, and at least another part of the second solar cell assembly is arranged in a different plane, parallel with the first plane.

In some embodiments of the disclosure, the solar cells are distributed over a first portion of the first surface of each solar cell assembly, and a second portion of the first surface is free from solar cells, and the second solar cell assembly overlaps with the first solar cell assembly in correspondence with the second portion of the first surface of the first solar cell assembly. The first portion is preferably substantially larger than the second portion. For example, the first portion is preferably at least five times larger than the second portion, preferably at least ten times larger.

In some embodiments of the disclosure, each solar cell assembly comprises a first terminal comprising a conductive region on the second side of the support adjacent a first edge of the support, and a second terminal comprising a conductive region on the first side of the support adjacent a second edge of the support, opposite said first edge of the support. That is, the support can have a substantially rectangular shape, and the terminals can be arranged in correspondence with, that is, adjacent to opposite peripheral edges of the support and on opposite sides of the support. One or both of said terminals can correspond to a part of the corresponding conductive layer extending in parallel with and adjacent to the corresponding edge. Thereby, the solar cell assemblies can easily be arranged in a string, in a partly overlapping manner, so that the first terminal of the second solar cell assembly is placed on top of and in contact with the second terminal of the first solar cell assembly, and so on.

In some embodiments of the disclosure, the solar cells on each solar cell assembly are connected in parallel. Thus, each solar cell assembly can include an appropriate amount of solar cells so as to produce, when in use, a desired amount of output current. The voltage level can be determined by choosing the number of solar cell assemblies that are connected in series in each string.

In some embodiments of the disclosure, each solar cell comprises a top surface including a contact of a first polarity type, and a rear surface including a contact of a second polarity type, the contact of second polarity type of each of the plurality of solar cells making electrical contact with the first conductive layer and the contact of the first polarity type of each of the plurality of solar cells being electrically connected to the second conductive layer. Thus, the arrangement with two conductive layers on opposite sides of the substrate serves on the one hand to connect the solar cells on the module in parallel, and on the other hand to provide for a simple and reliable interconnection of a plurality of solar cell assemblies or modules in series, in the partially overlapping manner described above.

In some embodiments of the disclosure, each solar cell assembly comprises a plurality of vias in the support extending from the first side of the support to the second side of the support, and a plurality of conductive interconnects extend from the first side of the support to the second side of the support, each respective interconnect making electrical contact with the contact of the first polarity type of a respective solar cell and extending through a respective via to make electrical contact with the second conductive layer disposed on the second side of the support. That is, the solar cells arranged on the first side of the support and connected to the first conductive layer via their rear contacts, are connected to the second conductive layer via interconnects, such as wires, passing through respective vias in the support.

In some embodiments of the disclosure, the first conductive layer comprises a plurality of strips, such as substantially rectangular or triangular strips, extending across the first side of the support. In some embodiments of the disclosure, each strip has a free end adjacent to one edge of the support, and another end where the strip is connected to a part of the conductive layer that extends along another edge of the support and which constitutes or forms part of the second terminal. In the embodiments in which vias are present in the support, the vias can be arranged in parallel with the strips, between adjacent strips. The solar cell assemblies can be arranged on a substrate, glued to the substrate.

In some embodiments of the disclosure, the solar cells have a surface area of less than 5 cm², or in some embodiments less than 1 cm², less than 0.1 cm², less than 0.05 cm², or less than 0.01 cm². For example, substantially rectangular—such as square—solar cells can be used in which the sides are less than 10, 5, 3, 2, 1 or even 0.5 mm long.

In some embodiments of the disclosure, the solar cells are III-V compound semiconductor multijunction solar cells. Such solar cells feature high efficiency but are relatively costly to manufacture. Thus, the solar array panel can comprise a plurality of series connected modules, each of which comprises a large amount of small solar cells connected in parallel. Errors in individual solar cells will not substantially affect the performance of the entire module, and the modules can be interconnected as described to provide for a reliable interconnection, minimizing the risk for errors and enhancing the reliability of the performance of each string of modules.

A further aspect of the disclosure relates to a method of manufacturing a solar array panel, comprising the steps of: providing a plurality of solar cell assemblies including at least a first solar cell assembly and a second solar cell assembly, each solar cell assembly comprising a support having a first side and an opposing second side, with a first conductive layer disposed on the first side of the support and a second conductive layer disposed on the second side of the support, and a plurality of solar cells mounted on the first side of the support; positioning the first solar cell assembly on a substrate; positioning the second solar cell assembly on the substrate so that the second solar cell assembly partially overlaps with the first solar cell assembly so that a portion of the second conductive layer of the second solar cell assembly overlaps with a portion of the first conductive layer of the first solar cell assembly; bonding the portion of the second conductive layer to the portion of the first conductive layer, so as to establish a mechanical and electrical connection between the two conductive layers.

In some embodiments, the connection can be established at one or more specific points or areas of the overlap, for example, along and across the entire overlap or most of it, or only at specific points. The way in which the bonding is carried out can be selected to optimize the performance in terms of, for example, simplicity of manufacture, reliability of the electrical and/or mechanical connection, flexibility of the panel, etc.

The step of attaching the two portions to each other can, for example, include the step of applying heat and/or pressure. In some embodiments of the invention, a conductive soldering material is applied in the area of the overlap, for example, on the portion of the first conductive layer or on the portion of the second conductive layer, prior to bringing the two portions in contact with each other.

In some embodiments of the disclosure, the method comprises the step of applying a conductive polyimide material onto a portion of the first conductive layer in correspondence with an edge of the first solar cell assembly, prior to placing the second solar cell assembly onto the structure.

In some embodiments of the disclosure, the supports are flexible so that the solar cell assemblies adapt their shape when placed on the structure, so that, for example, when the second solar cell assembly is placed on the structure partially overlapping with the first solar cell assembly, its shape is adapted so that, for example, a major portion of the second solar cell assembly is arranged on the structure and coplanar with a major portion of the first solar cell assembly, whereas a minor portion of the second solar cell assembly extends upwards from said structure and over a portion of the first solar cell assembly, in correspondence with an edge of the first solar cell assembly.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1A is a perspective view of a support that can be used for fabricating a module according to the present disclosure depicting metallization over the top and bottom surfaces;

FIG. 1B is a perspective view of the support of FIG. 1A after a step of forming a plurality of grooves in the bottom metal layer of the support in a first embodiment;

FIG. 1C is a perspective view of the support of FIG. 1A after a step of forming a plurality of spaced apart metal pads in the top metal layer of the support in a first embodiment;

FIG. 1D is a cross-sectional view of the support of FIG. 1C through the 1D-1D plane shown in FIG. 1C;

FIG. 1E is an enlarged perspective view of one of the metal pads on the support as shown in FIG. 1C;

FIG. 1F is a perspective view of the bottom of the support as shown in FIG. 1B after fabrication of two rows of vias;

FIG. 1G is a perspective view of a solar cell;

FIG. 1H is a perspective view of a solar cell mounted on the support;

FIG. 2A is a top perspective view of the support in a second embodiment in which only the bottom surface is metallized;

FIG. 2B is a top perspective view of the support of FIG. 2A in which two rows of vias have been fabricated;

FIG. 2C is a top perspective view of the support of FIG. 2B after metallization of the vias;

FIG. 2D is a bottom perspective view of the support of FIG. 2C depicting an embodiment of metallization of the bottom surface similar to that of FIG. 1B;

FIG. 2E is a top perspective view of a portion of the support of FIG. 2B after which two rows of solar cells have been mounted;

FIG. 2F is an enlarged perspective view of one of the solar cells in FIG. 2E mounted on the support;

FIG. 2G is a perspective view of a portion of the support of another embodiment in which an adhesive patch is applied to the surface of the support where a solar cell is to be attached;

FIG. 2H is a perspective view of the embodiment of FIG. 2G after bonding a solar cell to the support;

FIG. 2I is a perspective view of the solar cell of FIG. 2H after connection of a first interconnect to a pad on one via;

FIG. 3A is a top perspective view of the module with an array of solar cells mounted on the surface;

FIG. 3B is a top perspective view of the module of FIG. 3A after attachment of the interconnects;

FIG. 3C is a bottom plan view of the module of FIG. 3A depicting the location of the vias with respect to the array of solar cells on the top surface of the module, as depicted in dashed lines;

FIG. 4A is a schematic diagram of the one row of the components of the module;

FIG. 4B is a schematic diagram of a solar cell showing contacts of two polarities;

FIG. 4C is a schematic diagram of an array of solar cells as seen from the back side of the support;

FIG. 4D is a plan view of the array of FIG. 4C with all of the solar cells connected in parallel;

FIG. 4E is a plan view of the array of FIG. 4C with all of the solar cells connected in series;

FIG. 4F is a plan view of the array of FIG. 4C with some solar cells connected in series, and some in parallel;

FIG. 4G is a bottom plan view of the module showing the location of the solar cells on the top surface, as depicted in dashed line;

FIG. 4H is a bottom plan view of the module of FIG. 4G, further depicting the location of the vias with respect to the array of solar cells on the top surface of the module, as depicted in dashed lines;

FIG. 4I is a bottom plan view of the module of FIG. 4H with the solar cells connected in parallel;

FIG. 5 is a cross-sectional view of a III-V compound semiconductor solar cell that may be implemented on the module according to the present disclosure;

FIG. 6A is a cross-sectional view of two adjacent solar cells mounted on the module of FIG. 3A through the 6A-6A plane;

FIG. 6B is a cross-sectional view of the two solar cells of FIG. 3B through the 6B-6B plane after an interconnect has been attached to the top contact of the solar cell on the left, and the contact pad of the adjacent via;

FIG. 6C is a cross sectional view of the two solar cells of FIG. 3B through the 6C-6C plane after an interconnect has been attached to the bottom contact of another solar cell, and the contact pad of the adjacent via;

FIG. 7 depicts a wafer with a large number of small solar cells scribed and ready to be detached from the wafer;

FIG. 8 is a highly simplified perspective view of a space vehicle incorporating an array in which the deployable solar cell panel incorporates the interconnected solar cell module assemblies according to the present disclosure; and

FIG. 9 is a highly simplified perspective view of a space vehicle incorporating an array in which the deployable solar cell panel incorporates the interconnected solar cell module assemblies according to the present disclosure.

FIG. 10A is a schematic cross-sectional view of a first solar cell module of FIG. 6A mounted on a panel or supporting substrate during the first step of a panel assembly process;

FIG. 10B is a schematic cross-sectional view of a second solar cell module of FIG. 6A positioned and about to be coupled with the first solar cell module during the second step of a panel assembly process;

FIG. 10C is a schematic cross-sectional view of the second solar cell module shown in FIG. 7B being coupled with the first solar cell module shown in FIG. 7A during the third step of a panel assembly process; and

FIG. 10D is a schematic cross-sectional view of the second solar cell module shown in FIG. 7C being mounted on the panel or supporting substrate during the fourth step of a panel assembly process.

### DETAILED DESCRIPTION

Details of the present disclosure will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner.

Moreover, the drawings are not intended to depict every feature of the actual embodiment nor the relative dimensions of the depicted elements, and are not drawn to scale.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The present disclosure provides a process for the design and fabrication of a modular solar cell subassembly, and the interconnection of solar cells in the subassembly utilizing different interconnection elements and routing techniques.

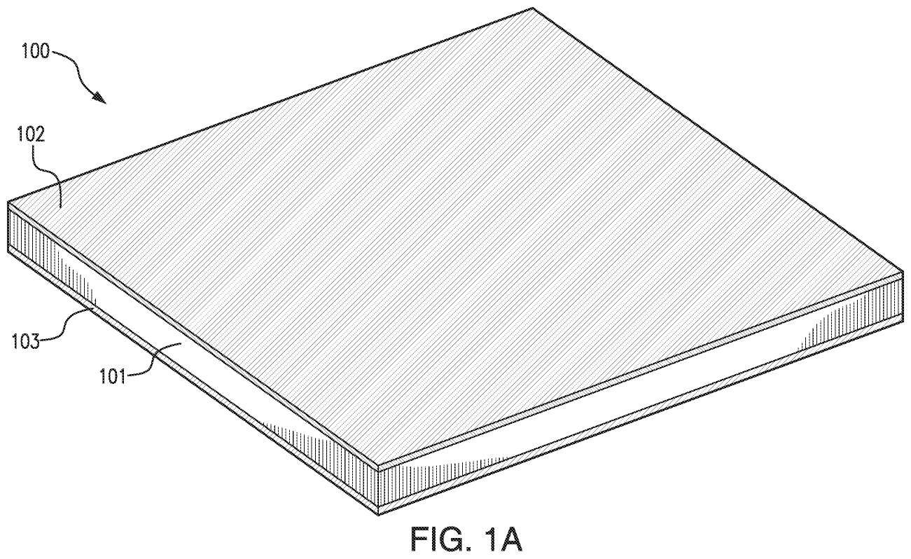

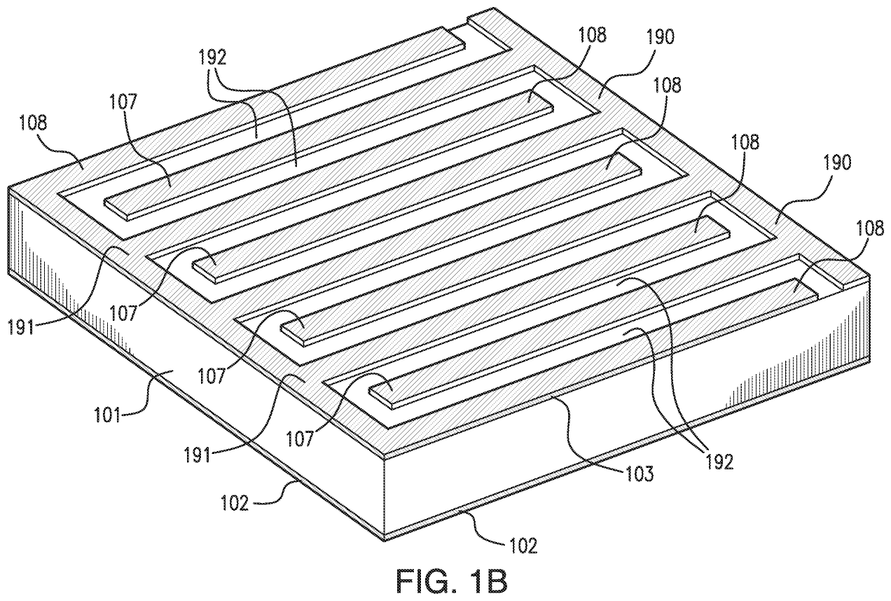

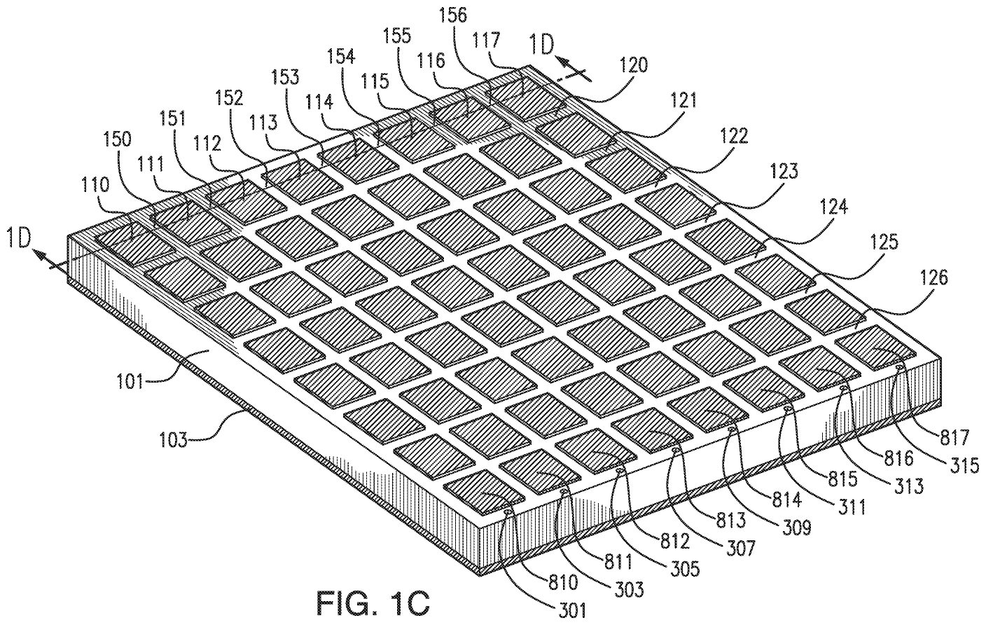

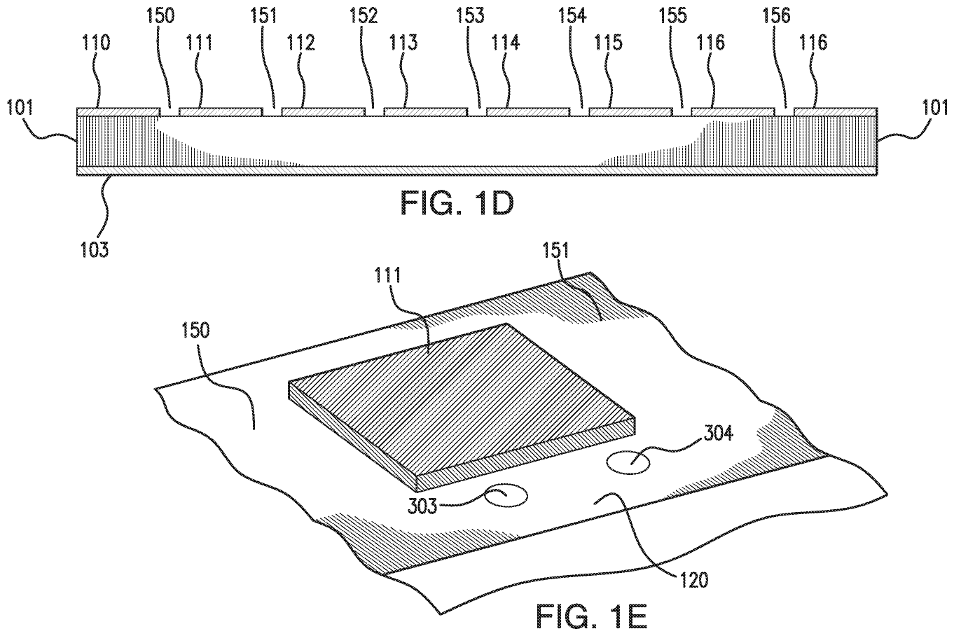

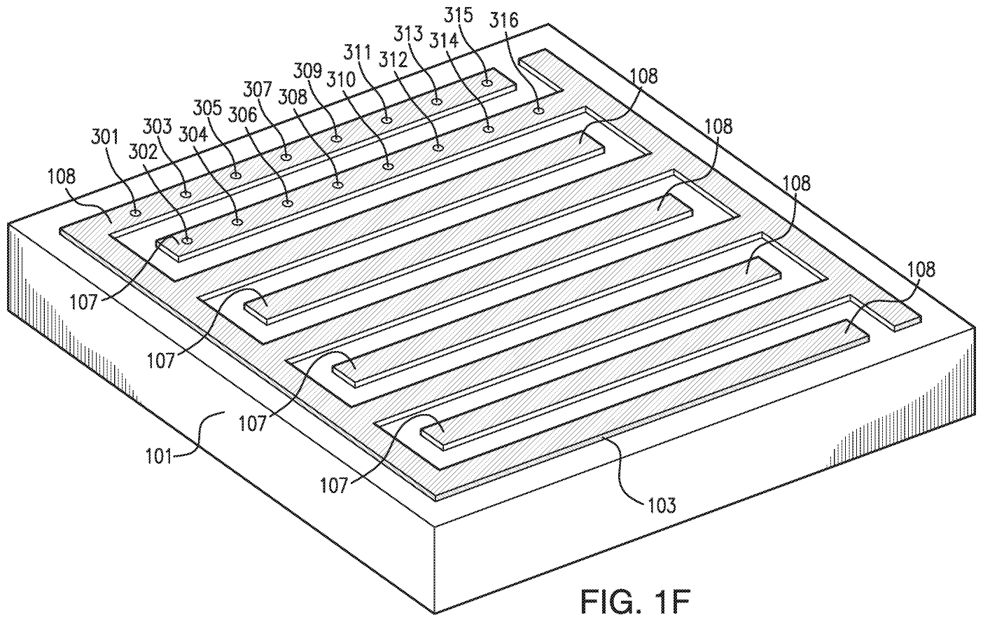

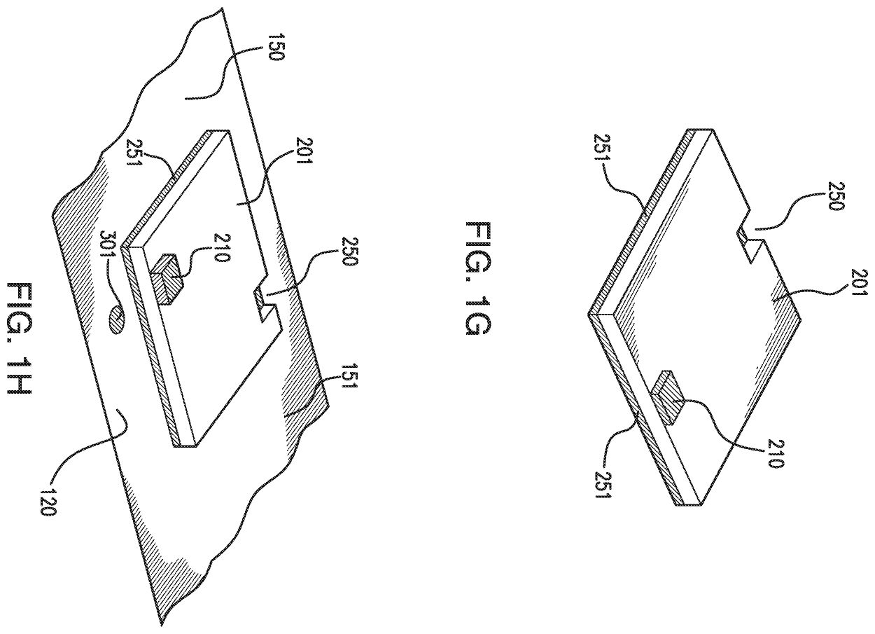

FIG. 1A illustrates an example of a support 100 that can be used in an embodiment of the disclosure in the fabrication of the modular subassembly. The support comprises an insulating support layer 101 and a conductive metal layer 102 arranged on a top surface of the support layer 101 and a conductive metal layer 103 arranged on a bottom surface of the support layer 101. In some embodiments of the disclosure, the metal layer 102 is a copper layer, having a thickness in the range of from 1 μm and up to 50 μm. In some embodiments of the disclosure, the support layer 101 is a KAPTON® sheet. The chemical name for KAPTON® is poly (4,4′-oxydiphenylene-pyromellitimide). A polyimide film sheet or layer may also be used. Preferably the metal layer is attached to the support layer in an adhesive-less manner, to limit outgassing when used in a space environment. In some embodiments of the disclosure the support layer can have a thickness in the range of 1 mil (25.4 μm) to 4 mil (101.6 μm). In some embodiments of the disclosure, a support can be provided comprising KAPTON®, or another suitable support material, on both sides of the metal film 102, with cut-outs for the attachment of solar cells and interconnects to the metal film. In some embodiments of the disclosure, the metal film layer 103 at the bottom surface of the support is of the same material and has the same or a similar thickness as the metal film layer 102 at the top surface of the support. In some embodiments, the two metal film layers are of different materials and/or have different thicknesses.

Although the support 100 is depicted in FIG. 1A as the size and shape of the ultimate module, which may be a square, rectangular or another geometrically shaped element ranging from 1 inch to 6 inches on a side, the support 100 may be fabricated out of a roll or larger support material such as a polymide film. Such material may be automatically processed and cut to produce the individual support 100 depicted in FIG. 1A, or subsequently depicted processed structures. A description of such fabrication processes goes beyond the scope of the present disclosure, but is described in the related applications.

In some embodiments, the support 100 may be cut to a different geometric shape, e.g. triangular, hexagonal, octagonal, or with irregular or non-linear edges, with one or more legs or extensions that support other electronic components or conductive traces that attach to the support.

FIG. 1B is a perspective view of the support 100 of FIG. 1A after a step of forming a plurality of grooves in the bottom metal layer 103 of the support in a first embodiment. FIG. 1B illustrates the support 100 of FIG. 1A after a step in which a portion of the metal layer 103 has been removed, by for example etching or laser scribing, whereby channels or grooves 192 are formed traversing the metal layer 103, separating it into at least a plurality of strips 107, 108, extending in parallel and in some embodiments connected to each other at a terminal 190, 191 respectively on opposing peripheral edges of the support 100.

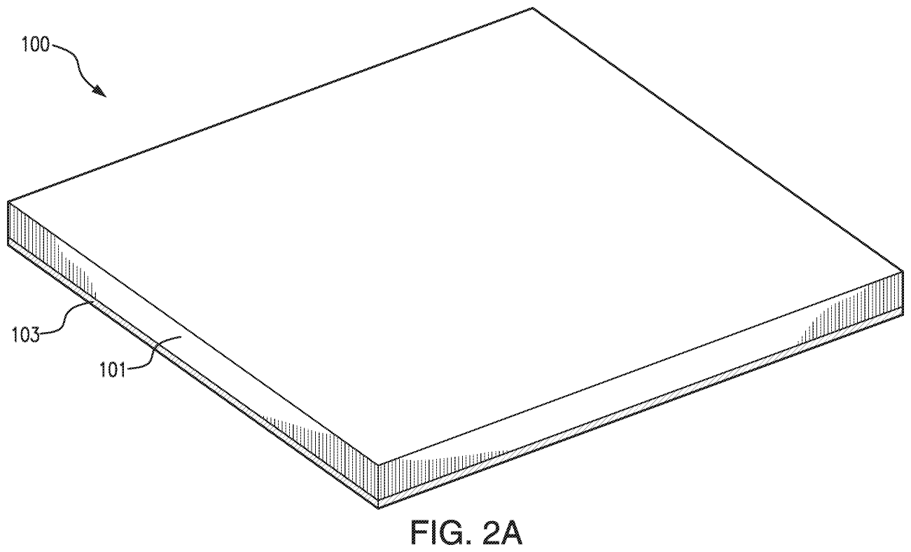

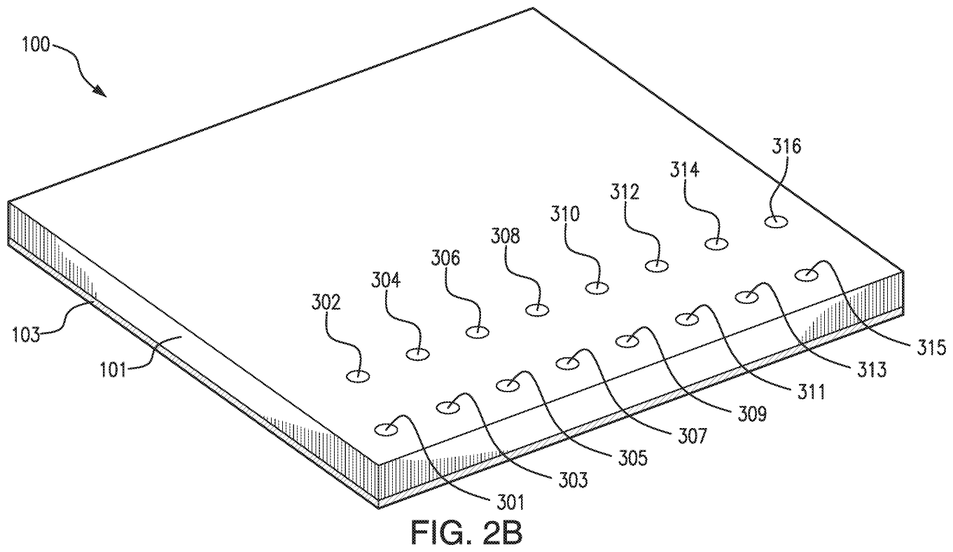

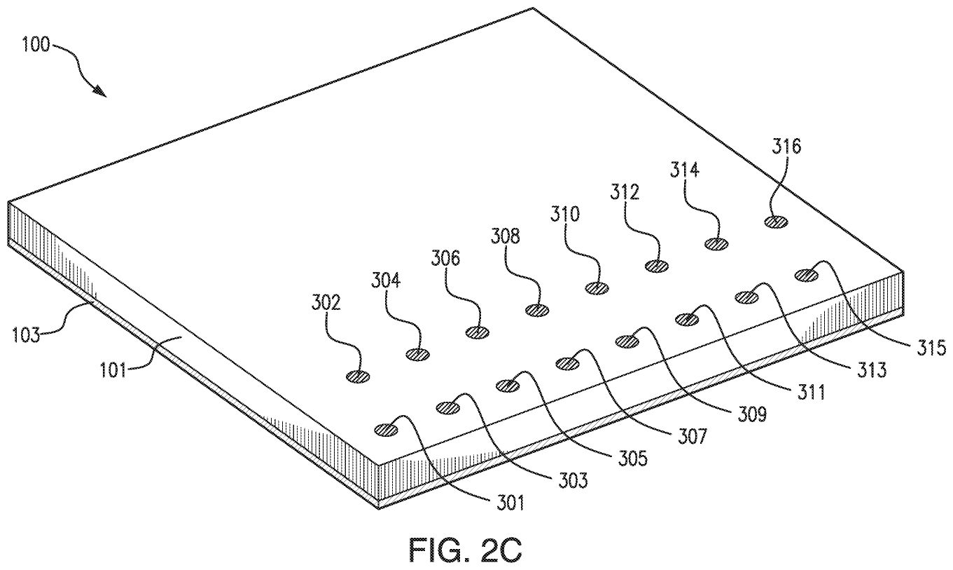

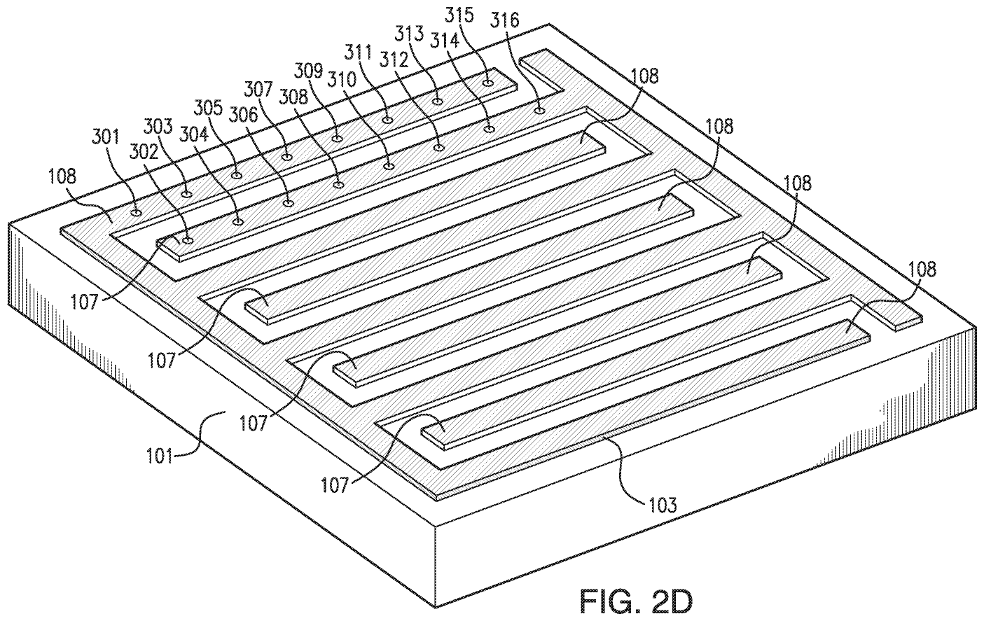

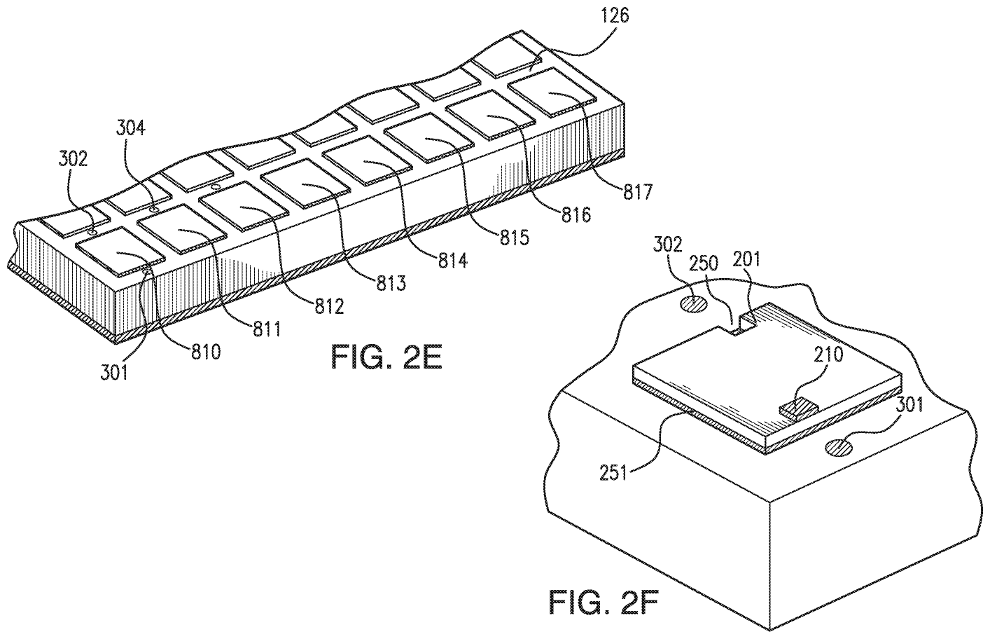

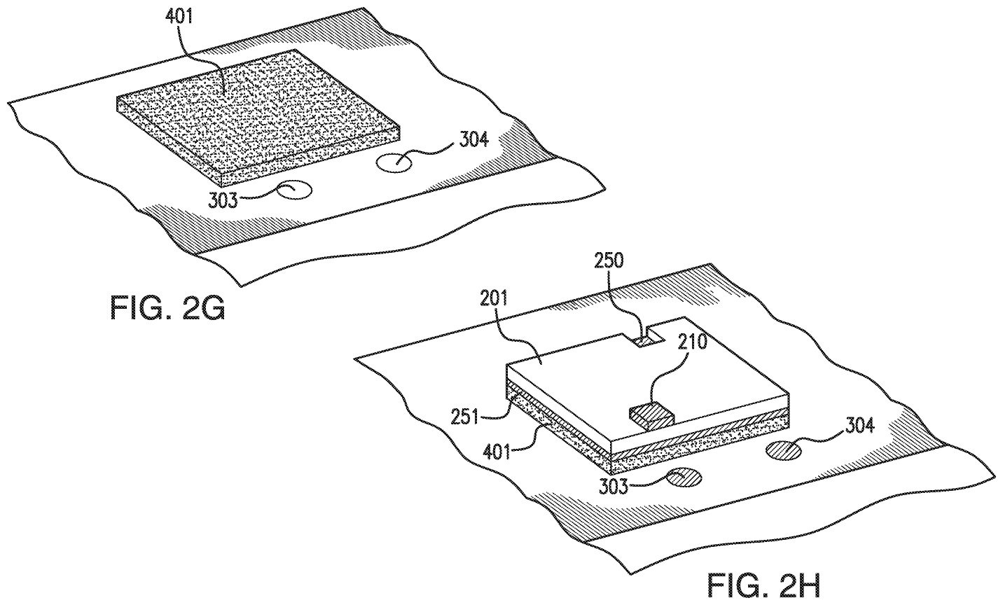

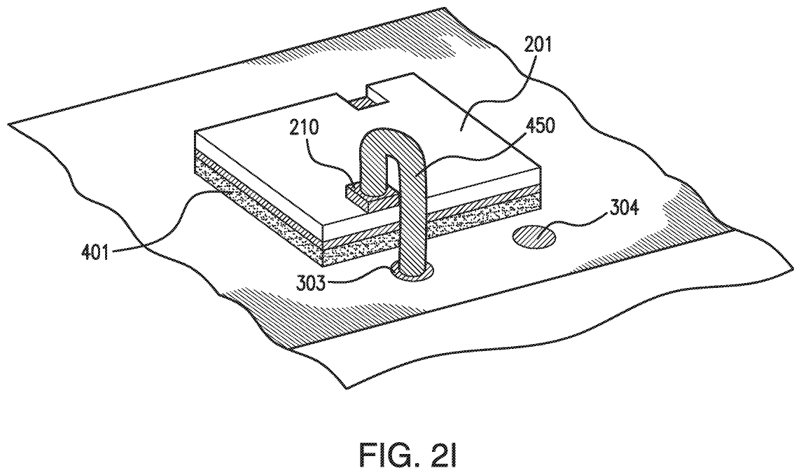

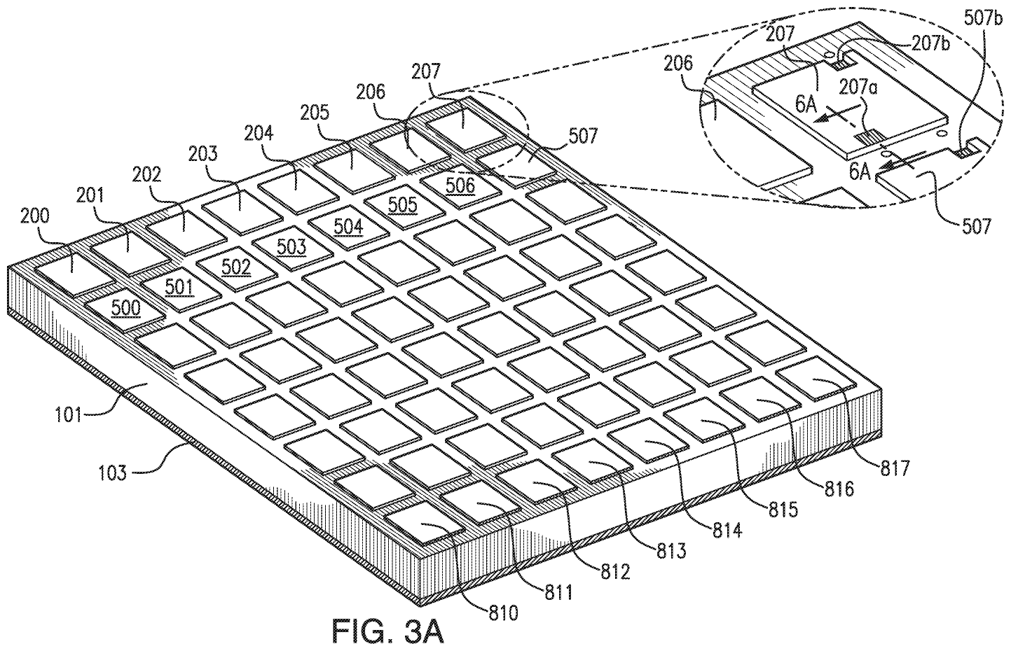

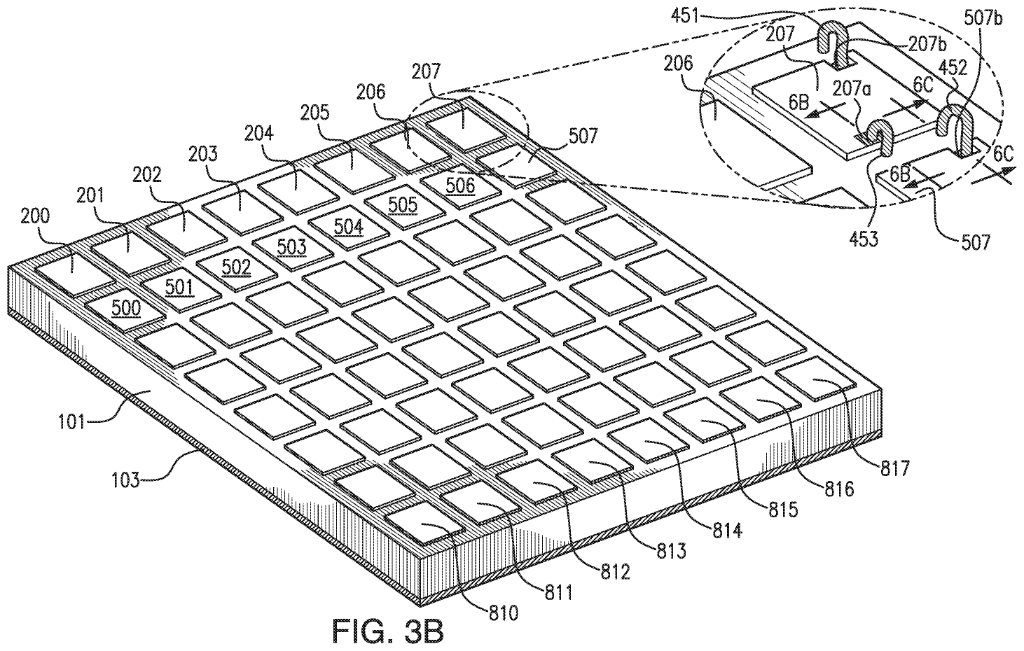

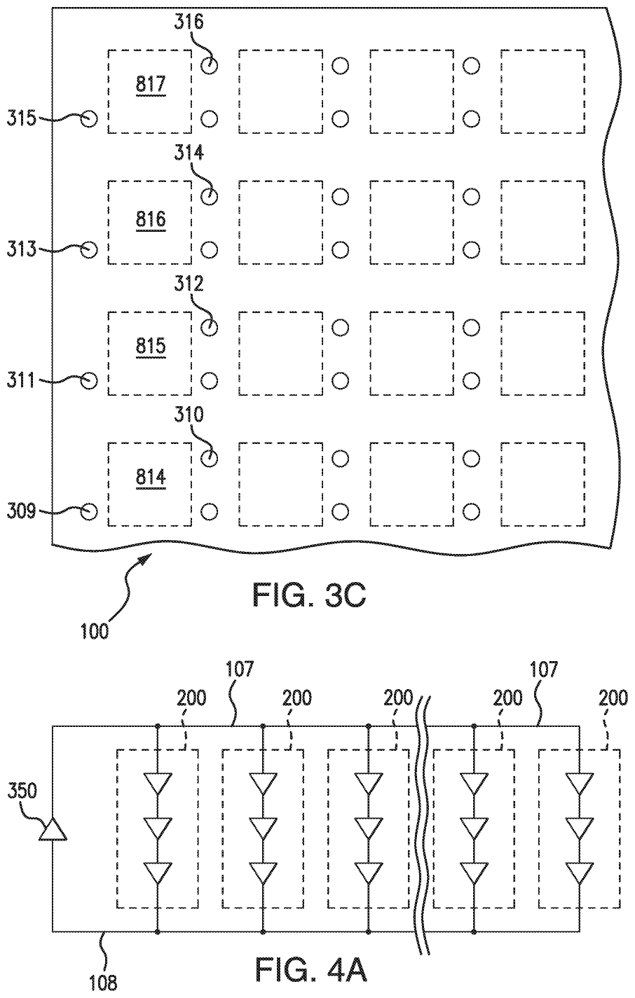

In another embodiment, the grooves etc. are V-shaped or triangular, and so are the strips such as depicted in FIGS. 2B and 3C of parent application Ser. No. 14/719,111. The use of this kind of strips the width of which increases along the strip when moving from the free end of the strip to the end where the strip is connected to the terminals 190, 191, is that when in use and with solar cells arranged in a row along the strip 180, current will flow in one direction, and current will be lowest towards the free end of the strip (where the current corresponds to the one produced by one solar cell), and higher towards the end where the strip connects to the terminal 190, 191 (where the current is the sum of the currents produced by the solar cells arranged on the strip). Thus, the need for a sufficient cross section of conductive material is higher towards the end where the strip mates with the terminals 190, 191. Thus, the increasing width corresponds to an optimization of the use of conductive material, which can be important especially for space applications.

FIGS. 1C and 1D show the support of FIG. 1A after a step of forming a plurality of spaced apart metal pads 110-117, 810-817 in the top metal layer 102 of the support, for example by etching or laser scribing, creating channels or grooves 120-126 and 150-156. FIG. 1E shows an enlarged perspective view of one of the metal pads 111, placed adjacent to two vias 303 and 304. Further vias 301, 305, 315 are shown in FIG. 1C.

FIG. 1F is a perspective view of the bottom of the support as shown in FIG. 1B after fabrication of two rows of vias 301, 303,315 and 302, 304 . . . , 306, respectively. These vias can be used to connect solar cells placed on the metal pads 110-117, to the strips formed in the bottom metal layer 103. The vias can be filled with conductive material, or be used to accommodate for example an interconnecting wire. When the vias are filled with a conductive material, interconnects such as wires can be electrically connected to the top and bottom surfaces or contact pads of the vias and to respective contacts on the solar cells, so as to establish electrical connection between the electrical contacts on the solar cells and the bottom metal layer 103.

FIG. 1G is a perspective view of a solar cell 201 with a top surface having a contact pad 201 corresponding to a contact of a first polarity type, a bottom surface with a metal layer 251 corresponding to a contact of a second polarity type. A cut-out 250 provides access to the contact of the second polarity type from above.

FIG. 1H is a perspective view of a solar cell 201 mounted on the support, adjacent to a via 301. The solar cell c a n in this embodiment be placed on one of the metallic contact pads 110-117 shown in FIG. 1C.

FIG. 2A is a top perspective view of the support 100 in a second embodiment in which only the bottom surface is metallized, so that the support layer 101 features a conductive layer 103 on only one of its two sides.

FIG. 2B is a perspective view of the support of FIG. 2A after the next process step of providing vias 301, 303, . . . 315 in a first row, and 302, 304, . . . 316 in a second row, extending into or through the support 100 according to the present disclosure. The vias can be provided using any suitable means.

FIG. 2C is a perspective view of the support of FIG. 2B illustrates in the first embodiment how the vias 301, . . . 315 and 302, . . . 316 may be plated with metal so as to form a conductive path from the bottom metal layer 103 to the top surface of the support.

FIG. 2D is a bottom perspective view of the support of FIG. 2C in first embodiment and illustrates how the vias traverse the body 101 and emerge at the bottom surface thereof and stop at the top of the metal film strips 107 and 108. (Only the first two rows of vias 301, . . . 315 and 302, . . . 316 are shown for simplicity).

FIG. 2E is a perspective view of the support of FIG. 2C after the next process step of mounting a plurality of solar cells 810, 811, . . . 817 on a first row along the top surface of the support according to the present disclosure.

FIG. 2F is an enlarged perspective view of a single solar cell. Each solar cell has a top surface in which a contact pad of a first polarity (in the enlarged depiction represented by 210 for solar cell 207), such as a cathode contact pad, is provided. Two vias 301 and 302 are shown, adjacent to the solar cell.

FIG. 2G is a perspective view of a portion of the support of another embodiment in which an adhesive patch 401 is applied to the surface of the support where a solar cell is to be attached; the adhesive patch 401 can be used to adhere a solar cell to the support. Two vias 303 and 304 are shown.

FIG. 2H is a perspective view of the embodiment of FIG. 2G after bonding a solar cell to the support. The solar cell features a top contact with contact pad 210 corresponding to a contact of a first polarity type, and a conductive layer 251 at the bottom of the solar cell, corresponding to a contact of a second polarity type. This conductive layer 251 is placed on the adhesive patch 401. Access to the conductive layer 251 from above is provided for by the recess or cut-out 250.

FIG. 2I is a perspective view of the solar cell of FIG. 2H after connection of a first interconnect 450 to electrically connect the contact pad 210 to the conductive material filling via 303, thereby establishing contact between the contact pad 210 and the conductive portion 108 (see FIG. 2D) on the other side of the support.

FIG. 3A is a top perspective view of the module with an array of solar cells 200-207, 500-507, 810-817 mounted on the surface of the first side of the support. In the enlarged portion, a contact 207a of the first polarity type and two contacts 207b, 507b of the second polarity type of are shown in relation to two solar cells 207, 507.

FIG. 3B is a top perspective view of the module of FIG. 3A after attachment of three interconnects 451, 452 and 453, two of them attached to the contacts 207b, 507b of the second polarity type and one of them attached to the contact of the first polarity type 207a, in order to electrically connect these contacts to the respective conductive portions on the other side of the support, through the vias.

FIG. 3C is a bottom plan view of the module of FIG. 3A depicting the location of the vias 309-316 with respect to the array of solar cells 814-817 on the top surface of the module, as depicted in dashed lines. Each solar cell is arranged to be electrically connected to two of said vias, so that, for example, a contact of the second polarity type of solar cell 814 is connected to via 309, and the contact of the first polarity type of solar cell 814 is connected to via 310. In this way, the contacts of different solar cells can be electrically interconnected, in parallel or in series, through the vias and through the conductive portions 107 and 108 on the bottom side of the support (cf. for example FIG. 2D).

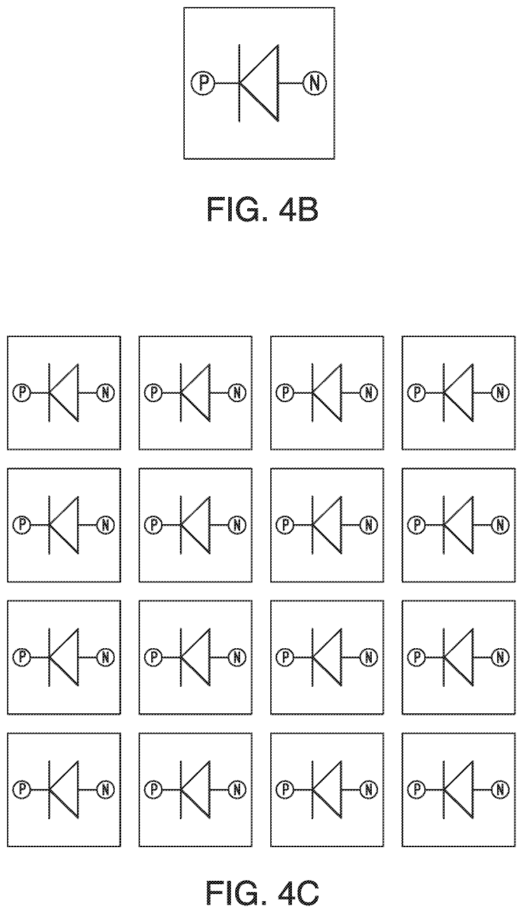

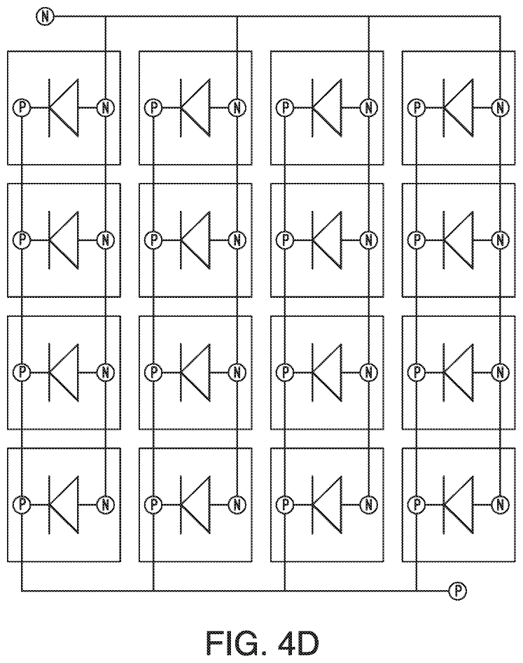

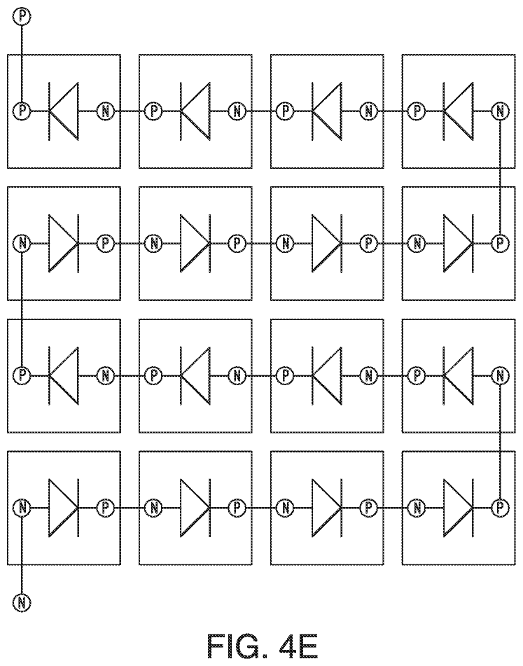

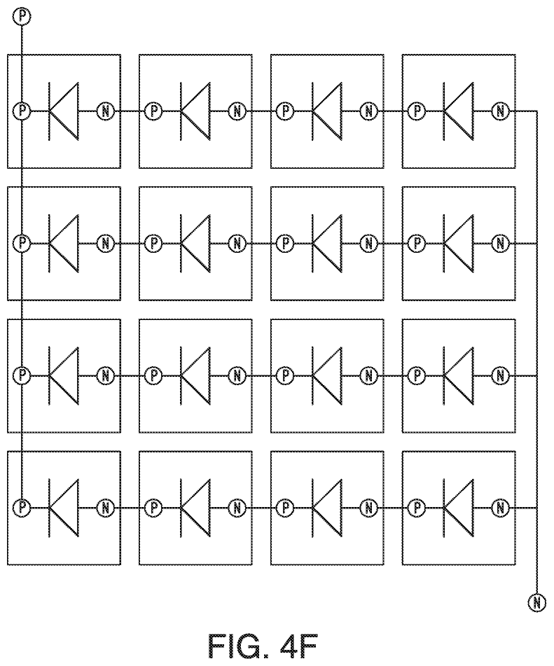

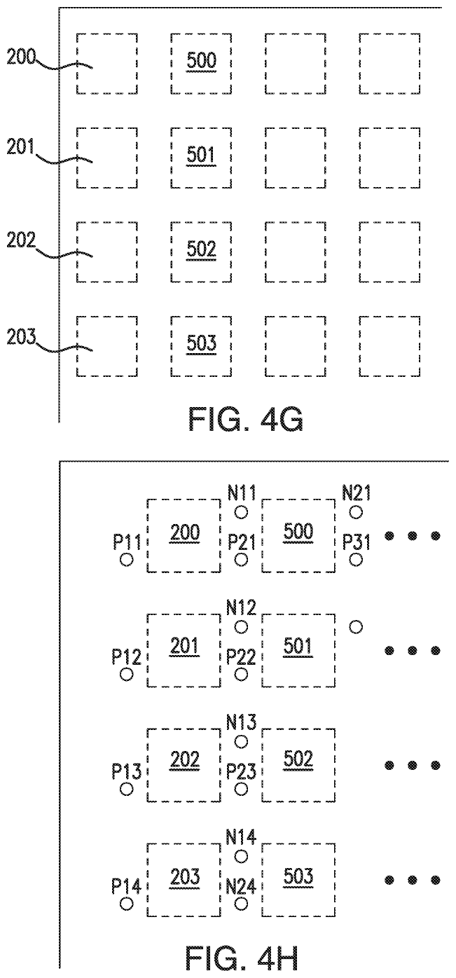

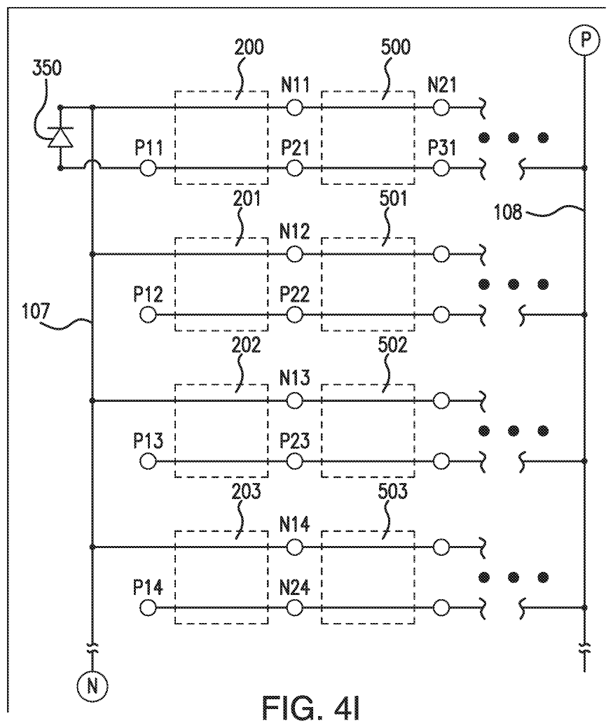

FIG. 4A is a schematic diagram of one row of the components of the module. A plurality of solar cells 200 are connected in parallel between two bus bars 107 and 108, corresponding to the second and to the first conductive portions, respectively, and with a bypass diode 350 common to the plurality of solar cells. Each solar cell is a multijunction solar cell.

Bypass diodes are frequently used for each solar cell in solar cell arrays comprising a plurality of series connected solar cells or groups of solar cells. One reason for this is that if one of the solar cells or groups of solar cells is shaded or damaged, current produced by other solar cells, such as by unshaded or undamaged solar cells or groups of solar cells, can flow through the by-pass diode and thus avoid the high resistance of the shaded or damaged solar cell or group of solar cells. Placing the by-pass diodes at the cropped corners of the solar cells can be an efficient solution as it makes use of a space that is not used for converting solar energy into electrical energy. As a solar cell array or solar panel often includes a large number of solar cells, and often a correspondingly large number of bypass diodes, the efficient use of the area at the cropped corners of individual solar cells adds up and can represent an important enhancement of the efficient use of space in the overall solar cell assembly.

In addition to the bypass diodes, a solar cell array or panel also incorporates a blocking diode that functions to prevent reverse currents during the time when the output voltage from a solar cell or a group of series connected solar cells is low, for example, in the absence of sun. Generally, only one blocking diode is provided for each set or string of series connected solar cells, and the blocking diode is connected in series with this string of solar cells. Often, since a panel includes a relatively large amount of solar cells that are connected in series, a relatively substantial blocking diode is required, in terms of size and electrical capacity. The blocking diode is generally connected to the string of solar cells at the end of the string. As the blocking diode is generally only present at the end of the string, not much attention has been paid to the way in which it is shaped and connected, as this has not been considered to be of major relevance for the over-all efficiency of the solar cell assembly. Standard diode components have been used.

FIG. 4B is a schematic diagram of a solar cell showing contacts of two polarities, for example, a contact of a first polarity type (henceforth: “N contact”) and a contact of a second polarity type (henceforth: “P contact”). This kind of solar cells can be arranged in an array, as schematically shown in FIG. 4C. Now, using the backplane of the support, these solar cells can be interconnected in different ways, for example, as shown in FIGS. 4D-4F.

FIG. 4D is a plan view of the array of FIG. 4C with all of the solar cells connected in parallel. This can be achieved, for example, by connecting the P contacts of the solar cells through one of the conductive portions 107 or 108, and the N contacts of all of the solar cells to another one of the conductive portions 108 or 107, through vias in the support, as previously explained.

FIG. 4E is a plan view of the array of FIG. 4C with all of the solar cells connected in series. Also, this can be carried out using, for example, conductive portions or traces at a rear surface of the support to interconnect a P contact of one solar cell with an N contact of a following solar cell, in a string of solar cells, etc. In other embodiments, at least part of the interconnections between P contacts and N contacts can be carried out directly using interconnects, without using the vias in the support.

FIG. 4F is a plan view of the array of FIG. 4C with some solar cells connected in series, and some in parallel. In some embodiments, this can be achieved by connecting a set of solar cells in series electrically connecting the P contact of one solar cell to the N contact of the next solar cell forming a string of solar cells, and thereafter connecting a plurality of said strings in parallel, by connecting the N contact of the first solar cell in each string to one of the conductive portions 107 or 108 (cf. FIG. 2D) on the rear surface of the support, and the P contact of the last solar cell in each string to another conductive portion 108 or 107 of the support, through the respective vias in the support.

FIG. 4G is a bottom plan view of the module showing the location of the solar cells 204-207, 504-507 on the top surface, as depicted in dashed lines.

FIG. 4H is a bottom plan view of the module of FIG. 4G, further depicting the location of the vias with respect to the array of solar cells on the top surface of the module, as depicted in dashed lines. For example, via P11 is associated to the contact of the second polarity type of solar cell 207, and via N11 is associated to the contact of the first polarity type of solar cell 207; via P21 is associated to the contact of the second polarity type of solar cell 507, and via N21 is associated to the contact of the first polarity type of solar cell; etc. Here, “associated” means that the via is used, in one way or another, to electrically connect the corresponding contact to a conductive portion at the bottom side of the support.

FIG. 4I is a bottom plan view of the module of FIG. 4H with the solar cells connected in parallel; this is achieved by interconnecting, on the one hand, all of the vias associated to the contacts of the first polarity type using a first conductive portion 108 on the bottom side of the support, and, on the other hand, all of the vias associated to the contacts of the second polarity type using a second conductive portion 107 on the bottom side of the support. Further, bypass diode 350 has been depicted in FIG. 4I. Thus, it can easily be understood how by using vias as described and appropriately designing the conductive portions on the bottom side of the support, for example, by removing selected portions of an original conductive layer 103, the desired interconnection of the solar cells mounted on the front side of the support can be achieved, using the vias. In some embodiments, in addition to the interconnection of solar cells using the backplane (the conductive portions on the bottom side of the support), solar cells can also be interconnected, for example, in series, by using interconnects directly interconnecting solar cells on the front side of the support.

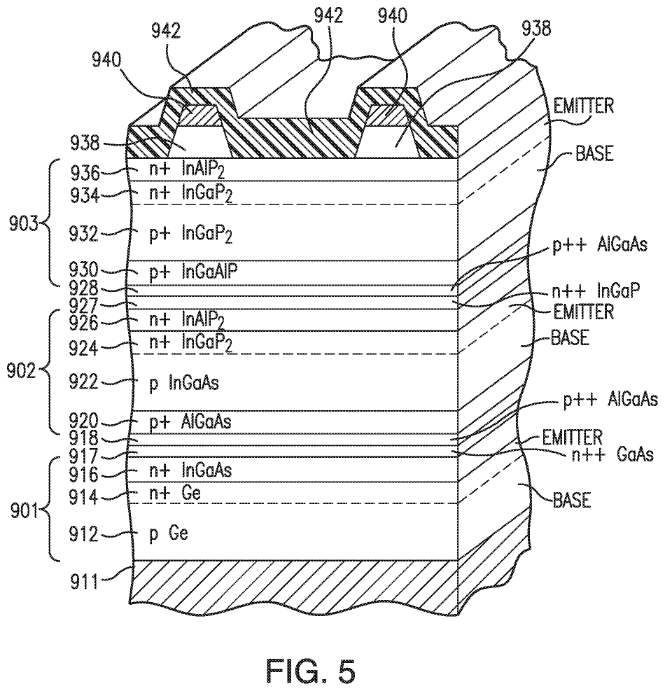

FIG. 5 is a cross-sectional view of a III-V compound semiconductor solar cell that may be implemented on the module according to the present disclosure. In the Figure, each dashed line indicates the active region junction between a base layer and emitter layer of a subcell.

As shown in the illustrated example of FIG. 5, the bottom subcell 901 includes a substrate 912 formed of p-type germanium (“Ge”) which also serves as a base layer. A contact pad 911 formed on the bottom of base layer 912 provides electrical contact to the multijunction solar cell 901. The bottom subcell 901 further includes, for example, a highly doped n-type Ge emitter layer 914, and an n-type indium gallium arsenide (“InGaAs”) nucleation layer 916. The nucleation layer is deposited over the base layer 912, and the emitter layer is formed in the substrate by diffusion of deposits into the Ge substrate, thereby forming the n-type Ge layer 914. Heavily doped p-type aluminum gallium arsenide (“AlGaAs”) and heavily doped n-type gallium arsenide (“GaAs”) tunneling junction layers 918, 917 may be deposited over the nucleation layer 916 to provide a low resistance pathway between the bottom and middle subcells.

In the illustrated example of FIG. 5, the middle subcell 902 includes a highly doped p-type aluminum gallium arsenide (“AlGaAs”) back surface field (“BSF”) layer 920, a p-type InGaAs base layer 922, a highly doped n-type indium gallium phosphide (“InGaP₂”) emitter layer 924 and a highly doped n-type indium aluminum phosphide (“AlInP₂”) or indium gallium phosphide (“GaInP”) window layer 926. The InGaAs base layer 922 of the middle subcell 902 can include, for example, approximately 1.5% In. Other compositions may be used as well. The base layer 922 is formed over the BSF layer 920 after the BSF layer is deposited over the tunneling junction layers 918 of the bottom subcell 904.

The BSF layer 920 is provided to reduce the recombination loss in the middle subcell 907. The BSF layer 920 drives minority carriers from a highly doped region near the back surface to minimize the effect of recombination loss. Thus, the BSF layer 920 reduces recombination loss at the backside of the solar cell and thereby reduces recombination at the base layer/BSF layer interface. The window layer 926 is deposited on the emitter layer 924 of the middle subcell 902. The window layer 926 in the middle subcell 902 also helps reduce the recombination loss and improves passivation of the cell surface of the underlying junctions. Before depositing the layers of the top cell 903, heavily doped n-type InGaP and p-type AlGaAs tunneling junction layers 927, 928 may be deposited over the middle subcell B.

In the illustrated example, the top subcell 903 includes a highly doped p-type indium gallium aluminum phosphide (“InGaAlP”) BSF layer 930, a p-type InGaP2 base layer 932, a highly doped n-type InGaP₂ emitter layer 934 and a highly doped n-type InAlP2 window layer 936. The base layer 932 of the top subcell 903 is deposited over the BSF layer 930 after the BSF layer 930 is formed over the tunneling junction layers 928 of the middle subcell 907. The window layer 936 is deposited over the emitter layer 934 of the top subcell after the emitter layer 934 is formed over the base layer 932. A cap or contact layer 938 may be deposited and patterned into separate contact regions over the window layer 936 of the top subcell 903. The cap or contact layer 938 serves as an electrical contact from the top subcell 903 to metal grid layer 940. The doped cap or contact layer 938 can be a semiconductor layer such as, for example, a GaAs or InGaAs layer.

After the cap or contact layer 938 is deposited, the grid lines 940 are formed. The grid lines 940 are deposited via evaporation and lithographically patterned and deposited over the cap or contact layer 938. The mask is subsequently lifted off to form the finished metal grid lines 940 as depicted in the Figure, and the portion of the cap layer that has not been metallized is removed, exposing the surface of the window layer 936.

As more fully described in U.S. patent application Ser. No. 12/218,582 filed Jul. 18, 2008, hereby incorporated by reference, the grid lines 940 are preferably composed of Ti/Au/Ag/Au, although other suitable materials may be used as well.

During the formation of the metal contact layer 940 deposited over the p+ semiconductor contact layer 938, and during subsequent processing steps, the semiconductor body and its associated metal layers and bonded structures will go through various heating and cooling processes, which may put stress on the surface of the semiconductor body. Accordingly, it is desirable to closely match the coefficient of thermal expansion of the associated layers or structures to that of the semiconductor body, while still maintaining appropriate electrical conductivity and structural properties of the layers or structures. Thus, in some embodiments, the metal contact layer 940 is selected to have a coefficient of thermal expansion (CTE) substantially similar to that of the adjacent semiconductor material. In relative terms, the CTE may be within a range of 0 to 15 ppm per degree Kelvin different from that of the adjacent semiconductor material. In the case of the specific semiconductor materials described above, in absolute terms, a suitable coefficient of thermal expansion of layer 940 would range from 5 to 7 ppm per degree Kelvin. A variety of metallic compositions and multilayer structures including the element molybdenum would satisfy such criteria. In some embodiments, the layer 940 would preferably include the sequence of metal layers Ti/Au/Mo/Ag/Au, Ti/Au/Mo/Ag, or Ti/Mo/Ag, where the thickness ratios of each layer in the sequence are adjusted to minimize the CTE mismatch to GaAs. Other suitable sequences and material compositions may be used in lieu of those disclosed above.

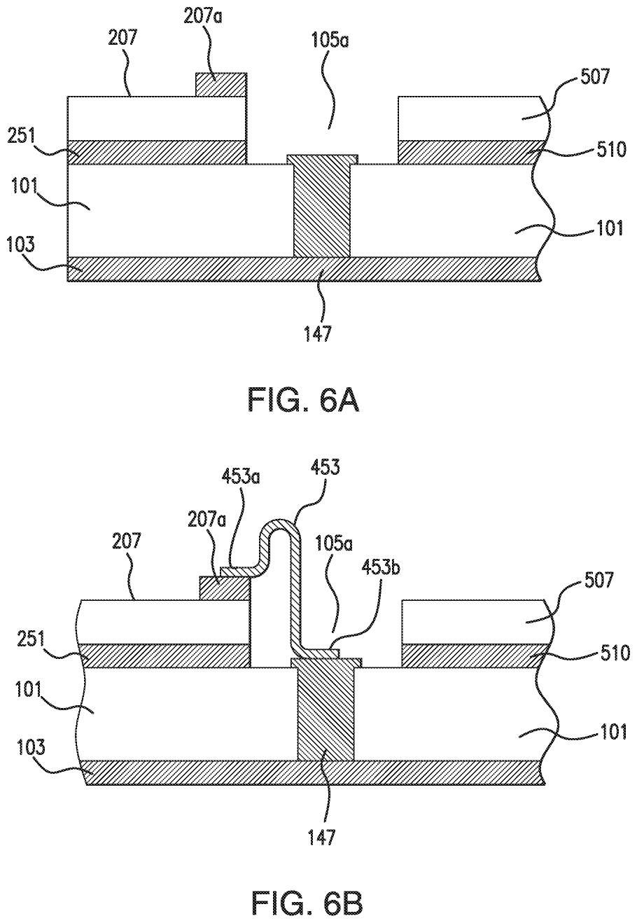

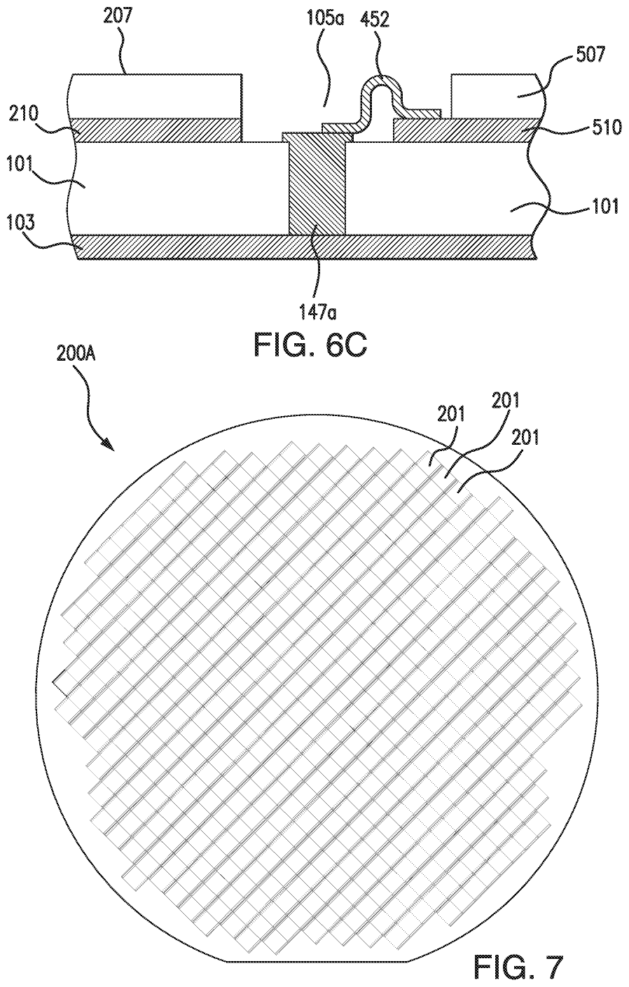

FIG. 6A is a cross-sectional view of the support of FIG. 3A through the 6A-6A plane shown in FIG. 3A, and shows the corresponding part of the assembly prior to incorporation of the wire including the channel 105a and the via 147.

FIG. 6B is a cross-sectional view of the support of FIG. 3A through the 6B-6B plane shown in FIG. 3A and illustrates the same part of the assembly after incorporation of the wire 453 in a first embodiment. Here, it can be seen how the wire 453 interconnects the contact pad 207a and the metal filling the via 147. A first end 453a of the wire is wire bonded to the contact pad 207a, and a second end 453b of the wire is wire bonded to the metal material filling the via 147, which in turn is connected to the bottom metal layer 103.

FIG. 6C is a cross-sectional view of the support of FIG. 3A through the 6C-6C plane shown in FIG. 3A and illustrates the same part of the assembly after incorporation of the wire 452 in a first embodiment. Here, it can be seen how the wire 452 interconnects the bottom metal layer 510 of the solar cell 507 and the metal layer 103 on the bottom surface of the support 101, through the via 147a.

As schematically shown in FIG. 7, obtaining individual solar cells by dividing a substantially circular solar cell wafer 200A into a large number of small solar cells 201, such as solar cells having areas of less than 5 cm² or less than 1 cm², enhances wafer utilization. Also, it is possible to discard solar cells from defective regions.

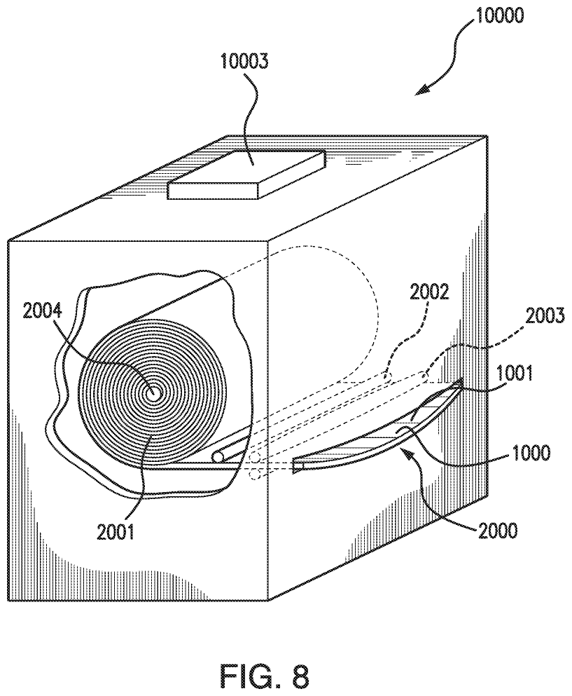

FIG. 8 is a highly simplified perspective view of a space vehicle 10000 incorporating a solar cell array 2000 in the form of a deployable flexible sheet including a flexible substrate 2001 on which solar cell modules 1000 and 1001 according to the present disclosure are placed. The sheet may wrap around a mandrel 20042 prior to being deployed in space with the aid of rollers 2002, 2003. The space vehicle 10000 includes a payload 10003 which is powered by the array of solar cell assemblies 2000.

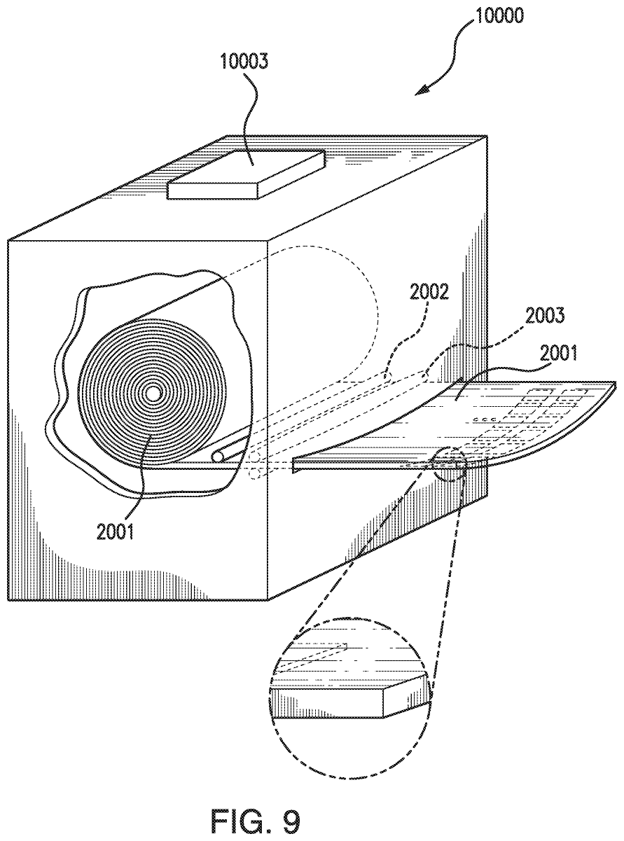

FIG. 9 is a highly simplified perspective view of a space vehicle 10000 incorporating a solar cell array 2000 of FIG. 8 as the deployable flexible sheet 2001 is being deployed.

Thus, an assembly of a plurality of solar cells connected in parallel is obtained, and this kind of assembly can be used as a subassembly or module, together with more subassemblies or modules of the same kind, to form a larger assembly, such as a solar array panel, including strings of series connected assemblies. For example, the present disclosure describes a space-qualified solar cell assembly designed for operation at AM0 and at a 1 MeV electron equivalent fluence of at least 5×10¹⁴ e/cm², the assembly comprising III-V compound semiconductor multijunction space-qualified solar cells including at least three subcells, including a ceria doped borosilicate glass supporting member that is 3 to 6 mils in thickness attached to each space-qualified solar cell with a transparent adhesive, wherein a combination of compositions and band gaps of the subcells is designed to maximize efficiency of the space-qualified solar cells at a predetermined time, after initial deployment when the space-qualified solar cells are deployed in space at AM0 and at an operational temperature in the range of 40 to 70 degrees Centigrade, the predetermined time being at least five years and referred to as the end-of-life (EOL), the space-qualified solar cell assembly comprising: a support comprising a first side and an opposing second side; a first conductive layer comprising first and second spaced-apart conductive portions disposed on the second side of the support; a plurality of space-qualified solar cells mounted on the first side of the support, each space-qualified solar cell of the plurality of space-qualified solar cells comprising a top surface including a contact of a first polarity type, and a rear surface including a contact of a second polarity type; a plurality of first vias in the support extending from the first side of the support to the second side of the support; a plurality of second vias in the support extending from the first side of the support to the second side of the support; a plurality of first conductive interconnects extending from the first side of the support to the first conductive portion of the first conductive layer, each respective interconnect making electrical contact with the contact of the first polarity type of a respective space-qualified solar cell and extending through a respective one of the first vias to make electrical contact with the first conductive portion of the first conductive layer disposed on the second side of the support; a plurality of second conductive interconnects extending from the first side of the support to the second conductive portion of the first conductive layer, each respective interconnect making electrical contact with the contact of the second polarity type of a respective space-qualified solar cell and extending through a respective one of the second vias to make electrical contact with the second conductive portion of the first conductive layer disposed on the second side of the support; and a first terminal of the module of a first polarity type disposed on the second side of the support and connected to the first conductive portion of the first conductive layer; and a second terminal of the module of a second polarity type disposed on the second side of the support and connected to the second conductive portion of the first conductive layer.

The figures are only intended to schematically show embodiments of the disclosure. In practice, the spatial distribution will mostly differ: solar cells are to be packed relatively close to each other and arranged to occupy most of the surface of the assembly, so as to contribute to an efficient space utilization from a W/m² perspective.

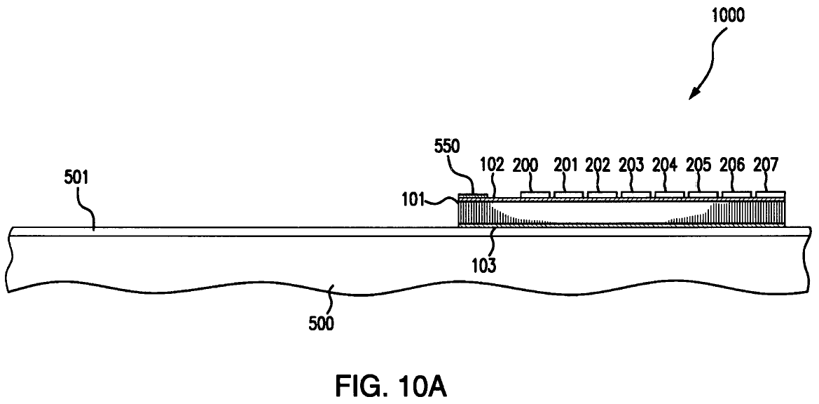

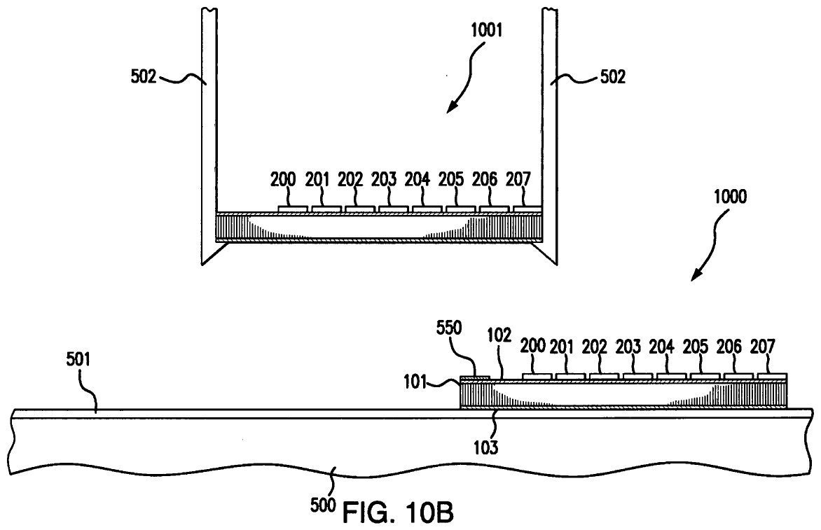

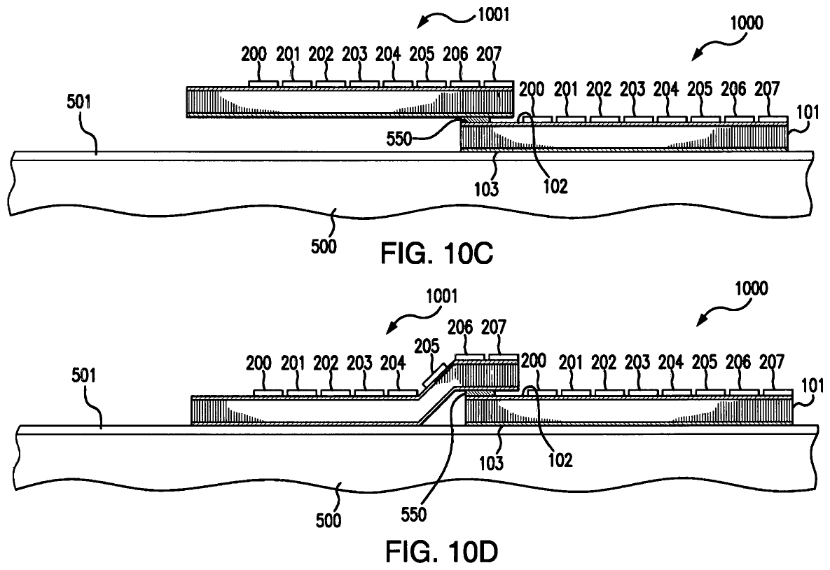

FIG. 10A is a schematic cross-sectional view of a first solar cell module or assembly 1000 of the type described above, mounted on a panel or supporting substrate 500 during the first step of a panel assembly process. An adhesive layer 501 is present on the top surface of the substrate 500 for attaching the assembly 1000 to the substrate 500. An interconnection pad 550, for example, of a conductive material—such as for example an indium alloy—that can be fused to bond two conductive layers to each other, is played adjacent to an edge of the assembly 1000, on top of the first conductive layer 102 and, more specifically, on the second terminal part of the first lateral conductive layer.

FIG. 10B schematically illustrates how a second solar cell assembly 1001, of the same type as the first solar cell assembly 1000, is being transferred to a position partially overlapping with the first solar cell assembly 1000, by a schematically illustrated pick-and-place apparatus 502.

FIG. 10C schematically illustrates a third step of the process, with the second solar cell module 1001 coupled with the first solar cell module 1000. It can be seen how the second solar cell module 1001 and the first solar cell module partially overlap with each other: more specifically, the second solar cell module 1001 is placed on top of a portion of the first conductive layer 102 of the first solar cell module 1000 that is free from solar cells, that is, a portion that corresponds to the second terminal described above.

FIG. 10D schematically illustrates the first and the second solar cell modules arranged on the supporting substrate after a fourth step of a panel assembly process. Here, a major portion of the second solar cell assembly 1001 has been aligned with the first solar cell assembly 1000 and glued to the supporting substrate 500 by the adhesive layer 501. The first terminal of the second solar cell assembly 1001 has been bonded to the second terminal of the first solar cell assembly 1000.

It is to be noted that the terms “front”, “back”, “top”, “bottom”, “over”, “on”, “under”, and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Furthermore, those skilled in the art will recognize that boundaries between the above described operations are merely illustrative. The multiple units/operations may be combined into a single unit/operation, a single unit/operation may be distributed in additional units/operations, and units/operations may be operated at least partially overlapping in time. Moreover, alternative embodiments may include multiple instances of a particular unit/operation, and the order of operations may be altered in various other embodiments.

In the claims, the word ‘comprising’ or ‘having’ does not exclude the presence of other elements or steps than those listed in a claim. The terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the claim includes the introductory phrases “one or more” or “at least one” and indefinite articles such as “a” or “an”. The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

The present disclosure can be embodied in various ways. The above described orders of the steps for the methods are only intended to be illustrative, and the steps of the methods of the present disclosure are not limited to the above specifically described orders unless otherwise specifically stated. Note that the embodiments of the present disclosure can be freely combined with each other without departing from the spirit and scope of the disclosure.

Although some specific embodiments of the present disclosure have been demonstrated in detail with examples, it should be understood by a person skilled in the art that the above examples are only intended to be illustrative but not to limit the scope of the present disclosure. It should be understood that the above embodiments can be modified without departing from the scope and spirit of the present disclosure which are to be defined by the attached claims.

1. A method of manufacturing a solar array panel, comprising the steps of:
providing a plurality of solar cell assemblies including at least a first solar cell assembly and a second solar cell assembly, each solar cell assembly comprising a support having a first side and an opposing second side, with a first conductive layer disposed on the first side of the support and a second conductive layer disposed on the second side of the support, and a plurality of solar cells mounted on the first side of the support;
positioning the first solar cell assembly on a fixture;
positioning the second solar cell assembly on the fixture so that the second solar cell assembly partially overlaps with the first solar cell assembly so that a first portion of the second conductive layer of the second solar cell assembly overlaps with a first portion of the first conductive layer of the first solar cell assembly; and bonding the first portion of the second conductive layer to the first portion of the first conductive layer, so as to establish a mechanical and electrical connection between the two conductive layers; and
providing a serial electrical interconnection between the first and second solar cell assemblies.

2. A method as defined in claim 1, wherein the support is flexible and is composed of a poly (4,4′-oxydiphenylene-pyromellitimide) material having a thickness between 25 and 100 microns.

3. A method as defined in claim 1, wherein each solar cell assembly comprises an array of discrete solar cells, each solar cell of the plurality of solar cells comprising a top surface including a contact of a first polarity type coupled to the first conductive layer and a rear surface including a contact of a second polarity type coupled to the second conductive layer.

4. A method as defined in claim 1, wherein the first portion of the first conductive layer is disposed on a first peripheral edge of the solar cell assembly, and the first portion of the second conductive layer is disposed on a second peripheral edge of the solar cell assembly opposite to the first edge.

5. A method as defined in claim 1, further comprising mounting the first and second interconnected solar cell assemblies on a panel.

6. A method as defined in claim 1, wherein the solar cells are mounted on the support in an automated manner by machine vision and a pick and place assembly tool.

7. A method as defined in claim 1, wherein the solar cells make up 95% or more of the total upper surface of the support.

8. A method as defined in claim 1, wherein the first conductive layer is an electrical bus interconnecting the bottom contacts of a subset of the solar cells on the solar cell assembly.

9. A method as defined in claim 1, further comprising providing a bypass diode electrically interconnecting the first conductive layer and the second conductive layer.

10. A method as defined in claim 9, wherein the solar cells and the bypass diode are located on the same side of the support

11. A method as defined in claim 1, further comprising bonding each solar cell to the first conductive layer by a conductive bonding material including an indium alloy.

12. A method as defined in claim 1, wherein each solar cell assembly has a substantially rectangular shape and a surface area in the range of 25 to 400 cm².

13. A method as defined in claim 1, wherein the step of bonding the first portion of the second conductive layer to the first portion of the first conductive layer is performed using a conductive soldering or welding material.

14. A method as defined in claim 1, wherein the first and second solar cell assemblies are arranged in colinear planes, with a portion of the support of the first solar cell assembly is curved so as to overlap with a portion of the support of the second solar cell assembly.

15. A method as defined in claim 1, further comprising forming a plurality of first vias in the support extending from the first side of the support to the second side of the support, and providing a plurality of first conductive interconnects extending from the first side of the support to the second side of the support, each respective first interconnect making electrical contact with the contact of the first polarity type at the top surface of a respective solar cell and extending through a respective via to make electrical contact with the first conductive portion of the second conductive layer disposed on the second side of the support.

16. A method as defined in claim 15, further comprising forming a plurality of second vias in the support extending from the first side of the support to the second side of the support;
a plurality of second conductive interconnects extending from the first side of the support to the second conductive portion of the first conductive layer, each respective interconnect making electrical contact with the contact of the second polarity type at the rear surface of a respective solar cell and extending through a respective one of the second vias to make electrical contact with a second conductive portion of the second conductive layer disposed on the second side of the support.

17. A method as defined in claim 16, wherein:
each of the first interconnects includes conductive material in a respective one of the first vias and a wire connecting the conductive material in the respective one of the first vias to the contact of the first polarity on the top surface of a respective one of the solar cells; and
each of the second interconnects includes conductive material in a respective one of the second vias and a wire connecting the conductive material in the respective one of the second vias to the contact of the second polarity on the rear surface of a respective one of the solar cells.

18. A method as defined in claim 1, wherein the solar cell assembly further comprises:
a first terminal of the assembly of a first polarity type disposed on the second side of the support and connected to the first conductive layer;
a second terminal of the assembly of a second polarity type disposed on the second side of the support and connected to the second conductive layer.

19. A method of manufacturing a solar array panel, comprising the steps of:
providing a roll of polyimide material;
providing conductive traces on and attaching electronic components to the upper surface of the roll;
providing a plurality of solar cell assemblies on the roll;
cutting the roll into at least a first solar cell assembly and a second solar cell assembly, each solar cell assembly comprising a portion of the roll forming a support having a first side and an opposing second side, with a first conductive layer disposed on the first side of the support and a second conductive layer disposed on the second side of the support, and a plurality of solar cells mounted on the first side of the support;
automatically placing the second solar cell assembly over a portion of the first solar cell assembly so that the second solar cell assembly partially overlaps with the first solar cell assembly such that a portion of the second conductive layer of the second solar cell assembly contacts and overlaps with a portion of the first conductive layer of the first solar cell assembly; and
bonding the portion of the second conductive layer to the portion of the first conductive layer, so as to establish a mechanical and electrical connection between the two conductive layers on the first and second solar cell assemblies respectively.

20. A solar cell array panel comprising:
a flexible support having a first side and an opposing second side, with a first conductive layer disposed on the first side of the flexible support, with a first conductive layer disposed on the first side of the support and a second conductive layer disposed on the second side of the support;
a plurality of solar cell assemblies including a first solar cell assembly and a second solar cell assembly, each solar cell assembly comprising a plurality of solar cells mounted on a first and a second flexible support respectively;
a plurality of solar cells mounted on the first side of the support wherein a contact of first polarity of the solar cell assembly is coupled to the first conductive layer and a contact of second polarity of the solar cell assembly is coupled to the second conductive layer;
the second solar cell assembly on the substrate so that a portion of the second solar cell assembly partially overlaps with the first solar cell assembly so that a portion of the second conductive layer of the second solar cell assembly overlaps with a portion of the first conductive layer of the first solar cell assembly and makes electrical contact thereto; and
the portion of the second conductive layer being bonded to the portion of the first conductive layer so as to establish a mechanical and electrical connection between the two conductive layers.
